(19) United States
(12) Patent Application Publication
(10) Pub. No.: US 2026/0026165 A1
(43) Pub. Date: Jan. 22, 2026

(54) DISPLAY DEVICE

(71) Applicant: LG Display Co., Ltd., Seoul (KR)

(72) Inventors: JungTae KIM, Paju-si (KR); DongGeun BAE, Goyang-si (KR)

(73) Assignee: LG Display Co., Ltd., Seoul (KR)

(21) Appl. No.: 19/222,815

(22) Filed: May 29, 2025

(30) Foreign Application Priority Data
Jul. 17, 2024 (KR) 10-2024-0094558

(51) Int. Cl. H10H 29/49; H10H 29/34; H10H 29/37; H10H 29/855

(52) U.S. Cl. CPC H10H 29/49; H10H 29/34; H10H 29/37; H10H 29/8552

(57) ABSTRACT

In one or more examples, a display device includes a substrate; a pixel configured by a plurality of main sub pixels and a plurality of redundancy sub pixels; one or more pixel driving circuits disposed on the substrate; a plurality of main micro LEDs which is electrically connected to the pixel driving circuit; and a plurality of redundancy micro LEDs which is electrically connected to the pixel driving circuit and the plurality of main micro LEDs is disposed in the plurality of main sub pixels and the plurality of redundancy micro LEDs is disposed in at least some of the plurality of redundancy sub pixels. Accordingly, in consideration of the defect of the main sub pixel, the redundancy micro LED is selectively transferred to only some redundancy sub pixel to reduce a total number of micro LEDs and save the manufacturing cost.

### CROSS-REFERENCE TO RELATED APPLICATIONS

This application claims the benefit of and priority to Korean Patent Application No. 10-2024-0094558 filed on Jul. 17, 2024, in the Korean Intellectual Property Office, the entire contents of which are incorporated herein by reference for all purposes.

### 1. Technical Field

The present disclosure relates to an apparatus and particularly to, for example, without limitation, a display device.

### 2. Description of Related Art

Display devices are being applied to various electronic devices, such as TVs, mobile phones, notebooks, and tablets.

As display devices, there are an organic light emitting display (OLED) which is a self-emitting device and a liquid crystal display (LCD) which requires a separate light source.

In recent years, a display device including a micro light emitting diode (mLED or μLED) as a light emitting element is attracting attention as a next generation display device. The micro LED is formed of an inorganic material, rather than an organic material so that lighting speed is faster, a luminous efficiency is excellent, and an image with a higher luminance may be displayed, as compared with the liquid crystal display or the organic light emitting display.

The description of related art should not be considered prior art merely because it is mentioned in or associated with this section. The description of related art includes information that describes one or more aspects of the subject technology, and the description in this section does not limit the scope of the invention.

### SUMMARY

An aspect of the present disclosure is to provide a display device with a simplified structure of a plurality of pixel circuits.

Another aspect of the present disclosure is to provide a display device in which a plurality of pixel circuits is integrated in one micro driver to be driven at a low power.

Still another aspect of the present disclosure is to provide a display device in which a redundancy micro LED is selectively transferred into only some redundancy sub pixel depending on whether the main micro LED is defective, to reduce a total number of micro LEDs.

Still another aspect of the present disclosure is to provide a display device in which some micro LEDs are additionally transferred only when a defective sub pixel is generated to save a manufacturing cost.

Aspects of the present disclosure are not limited to the above-mentioned aspects, and other aspects, which are not mentioned above, can be clearly understood by those skilled in the art from the following descriptions.

According to an aspect of the present disclosure, a display device includes a substrate; a pixel configured by a plurality of main sub pixels and a plurality of redundancy sub pixels; one or more pixel driving circuits disposed on the substrate; a plurality of main micro light emitting diodes (LEDs) which is disposed on the pixel driving circuit and is electrically connected to the pixel driving circuit; and a plurality of redundancy micro LEDs which is disposed on the pixel driving circuit and is electrically connected to the pixel driving circuit and the plurality of main micro LEDs is disposed in the plurality of main sub pixels and the plurality of redundancy micro LEDs is disposed in at least some of the plurality of redundancy sub pixels. Accordingly, in consideration of the defect of the main sub pixel, the redundancy micro LED is selectively transferred to only some redundancy sub pixel to reduce a total number of micro LEDs and save the manufacturing cost.

According to another aspect of the present disclosure, a display device includes a substrate, a plurality of pixels each including one pair of first sub pixels, wherein the one pair of first sub pixels includes a 1-1-th sub pixel and a 1-2-th sub pixel, a first micro light emitting diode (LED) which is disposed in at least one sub pixel of the one pair of first sub pixels, and a black matrix which includes a transmission hole overlapping one sub pixel of the one pair of first sub pixels. The plurality of pixels includes a first pixel in which the first micro LED is disposed in the 1-1-th sub pixel in the one pair of first sub pixels, a second pixel in which the first micro LED is disposed in the 1-2-th sub pixel in the one pair of first sub pixels, and a third pixel in which the first micro LED is disposed in each sub pixel of the one pair of first sub pixels. Accordingly, a 1-2-th sub pixel which is used instead of the defective 1-1-th sub pixel is provided to improve a quality of the display device.

Other detailed matters of the example embodiments are included in the detailed description and the drawings.

According to one or more aspects of the present disclosure, the plurality of pixel circuits is integrated in one pixel driving circuit to be efficiently driven at a lower power.

According to one or more aspects of the present disclosure, the plurality of pixel circuits is integrated in one micro driver to simplify the structure of the display device.

According to one or more aspects of the present disclosure, the redundancy micro LED is selectively transferred into only some redundancy sub pixels depending on whether the main micro LED is defective so that the number of redundancy LEDs is reduced and the manufacturing cost of the display device may be saved.

The effects according to one or more aspects of the present disclosure are not limited to the contents exemplified above, and more various effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a perspective view illustrating a display device according to an example embodiment of the present disclosure;

FIG. 2 is a plan view of a display device according to an example embodiment of the present disclosure;

FIG. 3 is an enlarged view of a display device according to an example embodiment of the present disclosure;

FIG. 4 is a view illustrating a circuit structure according to an example embodiment of the present disclosure;

FIGS. 5 to 7 are plan views of a display device according to an example embodiment of the present disclosure;

FIG. 8 is a cross-sectional view of a display device according to an example embodiment of the present disclosure;

FIG. 9 is a cross-sectional view of a display device according to an example embodiment of the present disclosure;

FIGS. 10A and 10B are cross-sectional views of a display device according to an example embodiment of the present disclosure;

FIGS. 11A to 11D are cross-sectional views for explaining a manufacturing process of a display device according to an example embodiment of the present disclosure; and

FIGS. 12 to 15 are views illustrating devices to which a display device according to example embodiments of the present disclosure is applied.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

In the following description, when a detailed description of well-known functions or configurations related to this document is determined to unnecessarily cloud a gist of the inventive concept, the detailed description thereof will be omitted or may be briefly discussed.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure.

Any implementation described herein as an “example” is not necessarily to be construed as preferred or advantageous over other implementations.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including”, “having”, and “consist of” used herein are generally intended to allow other components to be added unless the terms are used with the term “only”. Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When explaining temporal relationships, terms such as “after”, “following”, “subsequent to”, or “before”, etc., may include non-consecutive cases unless terms like “immediately” or “directly” are used.

Terms such as “first”, “second”, etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected”, “coupled”, “joined”, or “attached” to another component, it should be understood that the component may be directly connected, coupled, joined, or attached to the other component, but unless explicitly specified otherwise, it may also be indirectly connected, coupled, joined, or attached with another component intervening between each component.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

The features of various embodiments in the present disclosure may be partially or wholly combined or associated with each other, various technical interlocking and operations are possible, and each embodiment may be implemented independently of each other or may be implemented together in an associated relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure.

Hereinafter, an example embodiment of the present disclosure will be described in detail with reference to the drawings.

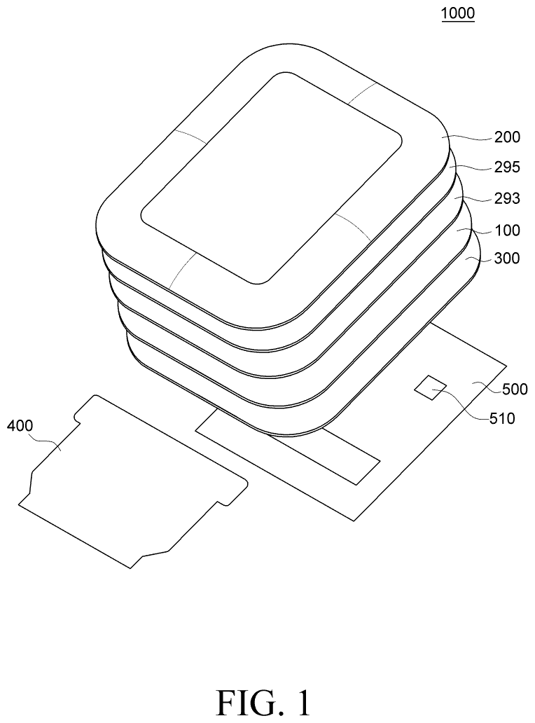

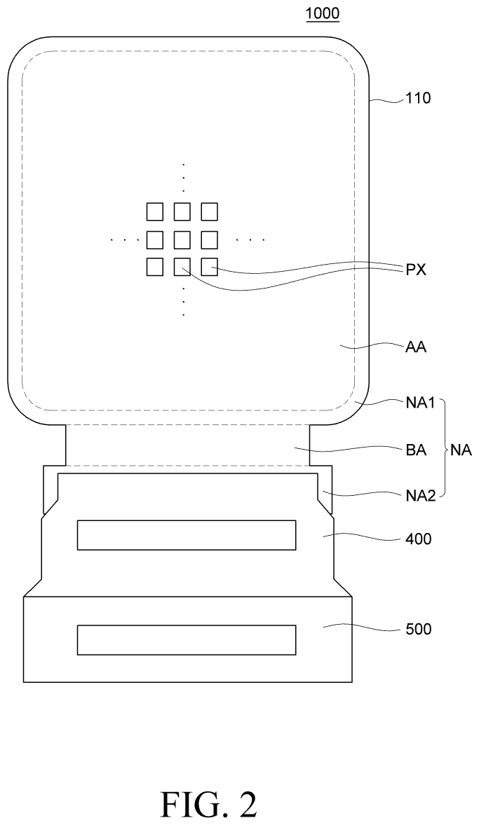

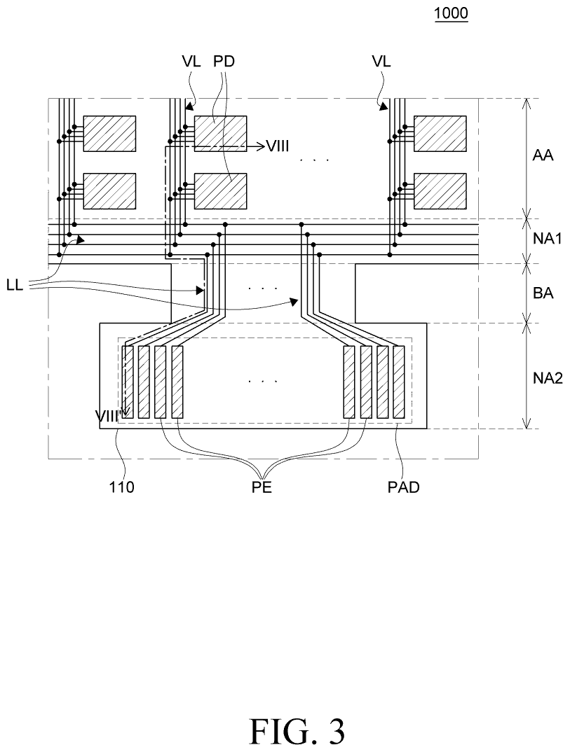

FIG. 1 is a perspective view illustrating a display device according to an example embodiment of the present disclosure. FIG. 2 is a plan view of a display device according to an example embodiment of the present disclosure. FIG. 3 is an enlarged view of a display device according to an example embodiment of the present disclosure.

Referring to FIGS. 1 to 3, a display device 1000 according to an example embodiment of the present disclosure may include a display panel 100, a polarization layer 293, an adhesive layer 295, a cover member 200, a support substrate 300, a flexible circuit board 400, and a printed circuit board 500.

For example, the display panel 100 of the display device 1000 may include a substrate 110. The substrate 110 may be a member which supports other components of the display device 1000. The substrate 110 is formed of an insulating material. For example, the substrate 110 may be formed of glass or resin. Further, the substrate 110 may also be formed of a material having a flexibility. For example, the substrate 110 may be formed of a plastic material having flexibility, such as polyimide (PI). However, the example embodiments of the present disclosure are not limited thereto.

The display panel 100 may implement information, videos, and/or images which are provided to users. For example, the display panel 100 may include an active area AA and a non-active area NA. For example, the substrate 110 may include an active area AA and a non-active area NA. However, the active area AA and the non-active area NA are not mentioned to be limited to the substrate 110, but mentioned for the entire display device 1000.

The active area AA is an area where images are displayed. The active area AA includes a plurality of pixels PX. Each of the plurality of pixels PX may be configured by a plurality of sub pixels. A plurality of light emitting diodes may be disposed in each of the plurality of sub pixels. The plurality of light emitting diodes may be configured in different manners depending on the type of the display device 1000. For example, when the display device 1000 is an inorganic light emitting display device 1000, the light emitting diode may be a light emitting diode (LED), a micro light emitting diode (micro LED), or a mini light emitting diode (mini LED), but the example embodiments of the present disclosure are not limited thereto. Hereinafter, the description will be made by assuming that the light emitting diode of the display device 1000 according to the example embodiment of the present disclosure is a micro LED, but the example embodiments of the present disclosure are not limited thereto.

The non-active area NA is an area where no image is displayed. In the non-active area NAA, various wiring lines and circuits for driving the plurality of pixels PX of the active area AA may be disposed. For example, in the non-active area NA, various wiring lines and driving circuits may be mounted and a pad unit PAD to which an integrated circuit and a printed circuit are connected may be disposed, but the example embodiments of the present disclosure are not limited thereto.

For example, the driving circuit may be a data driving circuit and/or a gate driving circuit, but the example embodiments of the present disclosure are not limited thereto. Wiring lines through which a control signal for controlling driving circuits is supplied may be disposed. For example, the control signal may include various timing signals including a clock signal, an input data enable signal, and synchronization signals, but the example embodiments of the present disclosure are not limited thereto. The control signal may be received through the pad unit PAD. For example, in the non-active area NA, link lines LL may be disposed to transmit signals. For example, driving components, such as the flexible circuit board 400 and the printed circuit board 500, may be connected to the pad unit PAD.

According to one or more aspects of the present disclosure, the non-active area NA may include a first non-active area NA1, a bending area BA, and a second non-active area NA2. For example, the first non-active area NA1 may be an area which encloses at least a part of the active area AA. The bending area BA is an area extending from at least one side, among a plurality of sides of the first non-active area NA1 and may be a bendable area. The second non-active area NA2 is an area extending from the bending area BA and the pad unit PAD may be disposed therein. For example, the bending area BA is in a bent state and the other areas of the substrate 110 excluding the bending area BA may be in a flat state. In this case, as the bending area BA is bent, the second non-active area NA2 may be located on a rear surface of the active area AA, but the example embodiments of the present disclosure are not limited thereto.

The active area AA of the substrate 110 or the display device 1000 may be configured with various shapes depending on a design of the display device 1000. For example, the active area may be configured with a rectangular shape formed with four rounded corners, but the example embodiments of the present disclosure are not limited thereto. As another example, the active area AA may be configured with a rectangular shape formed with four right-angled corners or a circular shape, but the example embodiments of the present disclosure are not limited thereto.

According to one or more aspects of the present disclosure, a width of the second non-active area NA2 in which the plurality of pad electrodes PE is disposed may be larger than a width of the bending area BA in which only a plurality of link lines LL is disposed. Further, a width of the active area AA in which the plurality of sub pixels is disposed may be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the example embodiments of the present disclosure are not limited thereto.

Referring to FIG. 3, a plurality of pixel driving circuits PD may be disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD may include a power line and a signal line for controlling emission on/off of the micro LED and/or an emission time. For example, the plurality of pixel driving circuits PD may be driving drives manufactured using a metal-oxide-silicon field effect transistor (MOSFET) manufacturing process on a semiconductor substrate, but the example embodiments of the present disclosure are not limited thereto. The driving driver includes a plurality of pixel driving circuits PD and may drive a plurality of sub pixels.

Referring to FIG. 1 together, the flexible circuit board 400 and the printed circuit board 500 may be disposed below the display panel 100. The flexible circuit board 400 and the printed circuit board 500 may be disposed at least at one edge of the display panel 100, but the example embodiments of the present disclosure are not limited thereto. One side of the flexible circuit board 400 is attached to the display panel 100 and the other side is attached to the printed circuit board 500, but the example embodiments of the present disclosure are not limited thereto. The flexible circuit board 400 may be a flexible film, but the example embodiments of the present disclosure are not limited thereto.

A pad unit PAD including a plurality of pad electrodes PE may be disposed in the second non-active area NA2. In the pad unit PAD, a driving component including one or more flexible circuit board (or a flexible film) 400 and the printed circuit board 500 may be attached or bonded. The plurality of pad electrodes PE of the pad unit PAD is electrically connected to one or more flexible circuit boards (or flexible films) 400 and may transmit various signals (or powers) from the printed circuit board 500 and the flexible circuit board (or a flexible film) 400 to the plurality of pixel driving circuits PD of the active area AA.

The flexible circuit board (or flexible film) 400 may be a film on which various components are disposed on a base film having ductility. For example, driving ICs such as a gate driver IC or a data driver IC may be disposed in the flexible circuit board (or flexible film) 400, but the example embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the example embodiments of the present disclosure are not limited thereto. The flexible circuit board (or flexible film) 400 may be attached or bonded onto the plurality of pad electrodes PE through a conductive adhesive layer, but the example embodiments of the present disclosure are not limited thereto.

The printed circuit board 500 may be a component which is electrically connected to one or more flexible circuit boards (or flexible films) 400 and supplies a signal to the driving IC. The printed circuit board 500 is disposed at one side of the flexible circuit board (or flexible film) 400 to be electrically connected to the flexible circuit board (or flexible film) 400. On the printed circuit board 500, various components for supplying various signals to the driving IC may be disposed. For example, on the printed circuit board 500, various components, such as a timing controller, a power source, a memory, or a processor, may be disposed. For example, the printed circuit board 500 may include a power management integrated circuit (PMIC), but the example embodiments of the present disclosure are not limited thereto.

The printed circuit board 500 may include at least one hole 510, but the example embodiments of the present disclosure are not limited thereto. An internal component which senses ambient light or temperature to be supplied to a plurality of sensors may be disposed in an area corresponding to at least one hole 510. For example, the internal component may include an ambient light sensor (ALS) or a temperature sensor, but the example embodiments of the present disclosure are not limited thereto. For example, the hole 510 may be a transmission hole, but the example embodiments of the present disclosure are not limited thereto.

Referring to FIG. 1, a polarization layer 293 may be disposed on the display panel 100. The polarization layer 293 may suppress or reduce the influence on the micro LED caused by light generated from an external light source and entering the display panel 100.

A cover member 200 may be disposed on the polarization layer 293. The cover member 200 may be a member for protecting the display panel 100. An adhesive layer 295 may be disposed between the polarization layer 293 and the cover member 200. The cover member 200 may be attached to the display panel 100 using the adhesive layer 295. The adhesive layer 295 may include an optically clear adhesive (OCA), an optically clear resin (OCR), or a pressure sensitive adhesive (PSA), but the example embodiments of the present disclosure are not limited thereto.

A support substrate 300 may be disposed between the display panel 100 and the printed circuit board 500. The support substrate 300 may reinforce a rigidity of the display panel 100. The support substrate 300 may be a back plate, but the example embodiments of the present disclosure are not limited thereto.

Referring to FIGS. 1 to 3, the plurality of link lines LL may be disposed in the non-active area NA. The plurality of link lines LL may be wiring lines which transmit various signals from one or more flexible circuit boards (or flexible films) 400 and the printed circuit board 500 to the active area AA. The plurality of link lines LL extends from the plurality of pad electrodes PE of the second non-active area NA2 toward the bending area BA and the first non-active area NA1 to be electrically connected to the plurality of driving lines VL of the active area AA. The plurality of pixel driving circuits PD is supplied with signals from one or more flexible circuit boards (or flexible films) 400 and the printed circuit board 500 through the driving line VL of the active area AA and the link line LL of the non-active area NA to be driven.

For example, the plurality of driving lines VL may be wiring lines for transmitting a signal output from the flexible circuit board (or flexible film) 400 and the printed circuit board 500 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) 400 and the printed circuit board 500 may be transmitted to each of the plurality of pixel driving circuits PD through the plurality of link lines LL and the plurality of driving lines VL.

As the bending area BA is bent, a part of the plurality of link lines LL is bent together. A stress is concentrated in the bent part of the link line LL, which causes a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the example embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto. The plurality of link lines LL may be configured by a multi-layered structure including various conductive materials. For example, the plurality of link lines LL may be configured with a triple layered structure of titanium (Ti)/aluminum (Al)/titanium (Ti), but the example embodiments of the present disclosure are not limited thereto.

The plurality of link lines LL may be configured with various shapes to reduce a stress. At least a part of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least a part of the plurality of link lines LL may be configured by various shapes of patterns. For example, at least a part of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape is repeatedly disposed. However, the example embodiments of the present disclosure are not limited thereto. Accordingly, in order to minimize or reduce a stress concentrated on the plurality of link lines LL and a crack caused thereby, a shape of the plurality of link lines LL may be various shapes including the above-mentioned shapes, but the example embodiments of the present disclosure are not limited thereto.

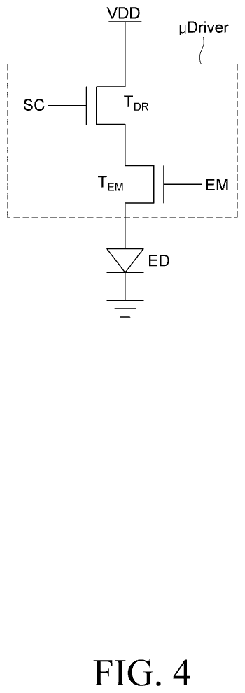

FIG. 4 is a view illustrating a circuit structure according to an example embodiment of the present disclosure.

A pixel driving circuit PD may include a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), but the present disclosure is not limited thereto. For example, eight micro LEDs (ED) may be connected to one micro driver (μDriver). As another example, 16 micro LEDs (ED) may be connected to one micro driver (μDriver) or 32 micro LEDs (ED) or 64 micro LED (ED) may be simultaneously connected to one micro driver (μDriver).

One micro driver (μDriver) may include a driving transistor TDR and an emission transistor TEM, but the example embodiments of the present disclosure are not limited thereto.

For example, a high potential power voltage VDD is applied to a first electrode of the driving transistor TDR and a first electrode of the emission transistor TEM is connected to a second electrode, and a scan signal SC may be applied to a gate electrode. The scan signal SC applied to the gate electrode of the driving transistor TDR is a direct current (DC) power and a fixed reference voltage may be applied in every frame, but the example embodiments of the present disclosure are not limited thereto.

The second electrode of the driving transistor TDR is connected to a first electrode of the emission transistor TEM, the micro LED (ED) is connected to a second electrode, and the emission signal EM may be applied to a gate electrode. The emission signal EM applied to the gate electrode of the emission transistor TEM may be a pulse width modulation signal which changes in every frame, but the example embodiments of the present disclosure are not limited thereto.

A first electrode of the micro LED (ED) is connected to the second electrode of the emission transistor TEM and a second electrode may be connected to the ground. For example, the first electrode is an anode electrode and the second electrode may be a cathode electrode, but the example embodiments of the present disclosure are not limited thereto.

Each of the driving transistor TDR and the emission transistor TEM may be an n-type transistor or a p-type transistor.

The driving transistor TDR is turned on by a scan signal SC applied from the timing controller T-CON to the micro driver (μDriver) and the emission transistor TEM is turned on by the emission signal EM. By doing this, the driving current is applied to the micro LED (ED) via the driving transistor TDR and the emission transistor TEM by the high potential power voltage VDD applied to the first electrode of the driving transistor TDR so that the micro LED (ED) may emit light.

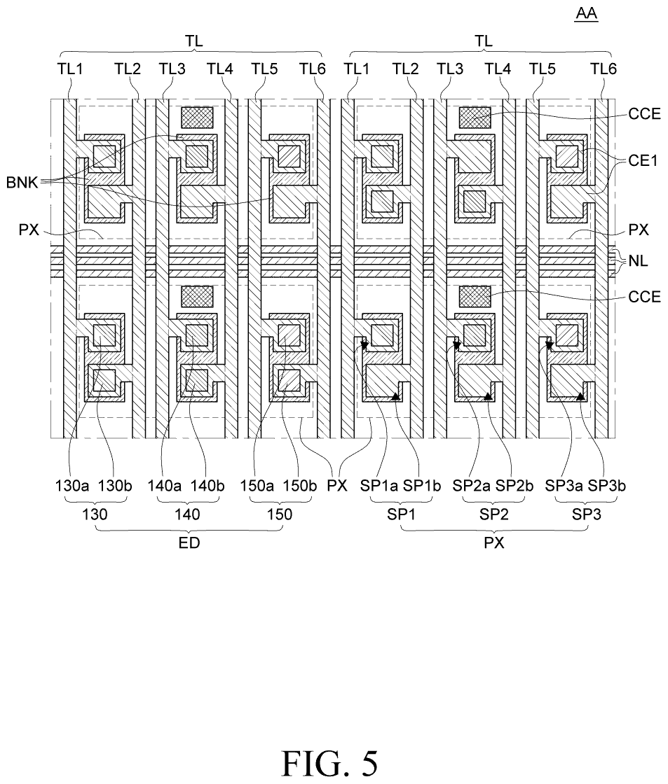

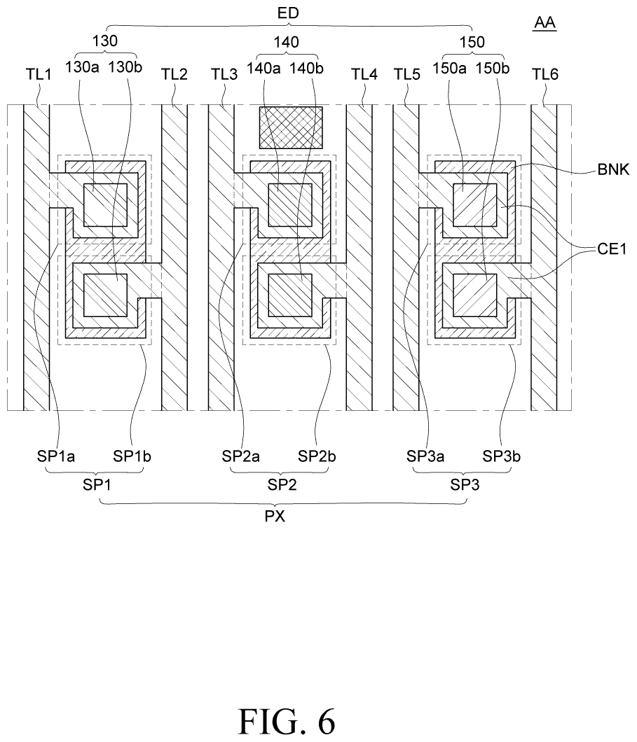

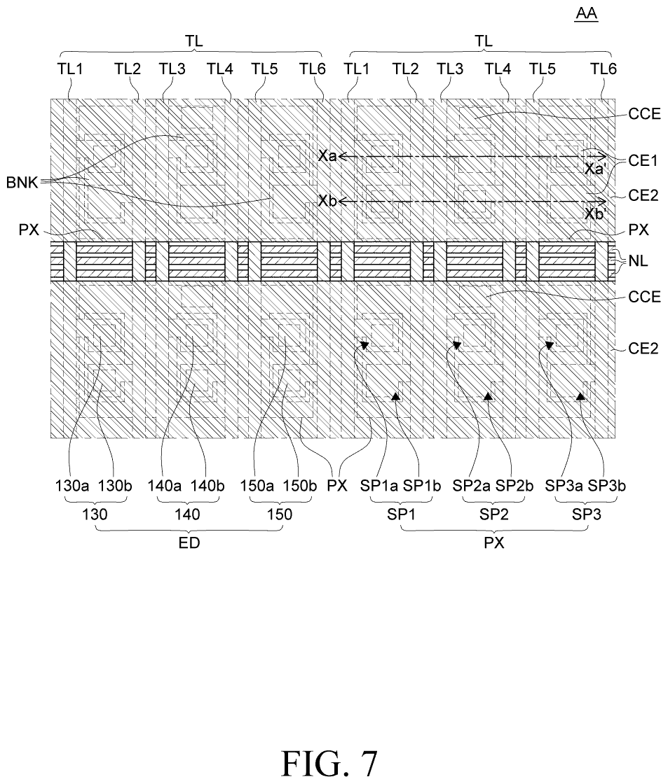

FIGS. 5 to 7 are plan views of a display device according to an example embodiment of the present disclosure; For example, FIG. 5 is an enlarged plan view of an active area including a plurality of pixels PX. For example, FIG. 6 is an enlarged plan view of an active area including one pixel PX. FIG. 6 is an enlarged plan view of a pixel PX on the left bottom of the plurality of pixels PX of FIG. 5. For example, FIG. 7 is an enlarged plan view of an active area including a plurality of pixels PX. In FIGS. 5 and 6, only a plurality of signal lines TL, a plurality of communication lines NL, a plurality of first electrodes CE1, a plurality of banks BNK, and a plurality of micro LEDs (ED) are illustrated, but the example embodiments of the present disclosure are not limited thereto. FIG. 7 is an enlarged plan view in which a plurality of second electrodes CE2 is additionally disposed to FIG. 5.

Referring to FIGS. 5 and 6, a plurality of pixels PX which is configured by a plurality of sub pixels may be disposed in the active area AA. Each of the plurality of sub pixels includes a micro LED (ED) and may independently emit light. The plurality of sub pixels may be disposed in a matrix by forming a plurality of rows and a plurality of columns, but the example embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 is a red sub pixel, another is a green sub pixel, and the third may be a blue sub pixel. The types of the plurality of sub pixels are illustrative, but the example embodiments of the present disclosure are not limited thereto.

Each of the plurality of pixels PX may include one or more first sub pixels SP1, one or more second sub pixels SP2, and one or more third sub pixels SP3. For example, one pixel PX may include one pair of first sub pixels SP1, one pair of second sub pixels SP2, and one pair of third sub pixels SP3. One pair of first sub pixels SP1 may be configured by a 1-1-th sub pixel SP1a and a 1-2-th sub pixel SP1b. One pair of second sub pixels SP2 may be configured by a 2-1-th sub pixel SP2a and a 2-2-th sub pixel SP2b. One pair of third sub pixels SP3 may be configured by a 3-1-th sub pixel SP3a and a 3-2-th sub pixel SP3b. For example, one pixel PX may include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the example embodiments of the present disclosure are not limited thereto.

The plurality of sub pixels which forms one pixel PX may be disposed in various ways. For example, in one pixel PX, one pair of first sub pixels SP1 is disposed on the same column, one pair of second sub pixels SP2 is disposed on the same column, and one pair of third sub pixels SP3 may be disposed on the same column. The first sub pixels SP1, the second sub pixels SP2, and the third sub pixels SP3 may be disposed on the same row. A number and a placement of the plurality of sub pixels which configures one pixel PX are illustrative, but the example embodiments of the present disclosure are not limited thereto.

The plurality of signal lines TL may be disposed in an area between the plurality of sub pixels. The plurality of signal lines TL may extend in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD may be transmitted to the first electrode CE1 of the plurality of sub pixels through the plurality of signal lines TL. For example, the first electrode CE1 may be an electrode which is electrically connected to the anode electrode 134 of the micro LED (ED). Therefore, the anode voltage from the signal line TL may be transmitted to the anode electrode 134 of the micro LED (ED) through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display device 1000. Further, a circuit which is disposed in each of the plurality of sub pixels is integrated in one pixel driving circuit PD so that highly efficient low power driving is possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to one pair of first sub pixels SP1, respectively. The third signal line TL3 and the fourth signal line TL4 may be electrically connected to one pair of second sub pixels SP2, respectively. The fifth signal line TL5 and the sixth signal line TL6 may be electrically connected to one pair of third sub pixels SP3, respectively.

The first signal line TL1 is disposed on one of one pair of first sub pixels SP1 and the first signal line TL1 may be disposed on the other one of one pair of first sub pixels SP1. The first signal line TL1 may be electrically connected to one first sub pixel SP1, between one pair of first sub pixels SP1, for example, to the first electrode CEL of the 1-1-th sub pixel SP1a. The second signal line TL2 may be electrically connected to the other first sub pixel SP1, between one pair of first sub pixels SP1, for example, to the first electrode CE1 of the 1-2-th sub pixel SP1b.

The third signal line TL3 is disposed on one of one pair of second sub pixels SP2 and the fourth signal line TL4 may be disposed on the other one of one pair of second sub pixels SP2. For example, the third signal line TL3 may be disposed to be adjacent to the second signal line TL2. The third signal line TL3 may be electrically connected to one second sub pixel SP2, between one pair of second sub pixels SP2, for example, to the first electrode CE1 of the 2-1-th sub pixel SP2a. The fourth signal line TL4 may be electrically connected to the other second sub pixel SP2, between one pair of second sub pixels SP2, for example, to the first electrode CE1 of the 2-2-th sub pixel SP2b.

The fifth signal line TL5 is disposed on one of one pair of third sub pixels SP3 and the sixth signal line TL6 may be disposed on the other one of one pair of third sub pixels SP3. For example, the fifth signal line TL5 may be disposed to be adjacent to the fourth signal line TL4. The sixth signal line TL6 may be disposed to be adjacent to the first signal line TL1 connected to the adjacent pixel PX. The fifth signal line TL5 may be electrically connected to one third sub pixel SP3, between one pair of third sub pixels SP3, for example, to the first electrode CE1 of the 3-1-th sub pixel SP3a. The sixth signal line TL6 may be electrically connected to the other third sub pixel SP3, between one pair of third sub pixels SP3, for example, to the first electrode CE1 of the 3-2-th sub pixel SP3b.

The plurality of signal lines TL may be formed of a conductive material. For example, the plurality of signal lines TL may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the example embodiments of the present disclosure are not limited thereto.

A plurality of communication lines NL may be disposed in an area between the plurality of pixels PX. The plurality of communication lines NL may be disposed to extend in the row direction in an area between the plurality of pixels PX. The plurality of communication lines NL is disposed in the area between the plurality of second electrodes CE2 and does not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the example embodiments of the present disclosure are not limited thereto.

According to one or more aspects of the present disclosure, a bank BNK may be disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs (ED) to the display device 1000. The plurality of micro LEDs (ED) may be transferred onto the plurality of banks BNK in the transfer process of the plurality of micro LEDs (ED). The plurality of banks BNK may be a bank pattern or a structure, but the example embodiments of the present disclosure are not limited thereto.

A bank BNK of the first sub pixel SP1, a bank BNK of the second sub pixel SP2, and a bank BNK of the third sub pixel SP3 may be disposed to be spaced apart from each other. The bank BNK of the first sub pixel SP1, the bank BNK of the second sub pixel SP2, and the bank BNK of the third sub pixel SP3 may be configured to be separated from each other. Therefore, the banks BNK of the first sub pixel SP1, the second sub pixel SP2, and the third sub pixel SP3 to which different types of micro LEDs (ED) are transferred may be easily identified.

The bank BNK of the 1-1-th sub pixel SP1a and the bank BNK of the 1-2-th sub pixel SP1b may be connected to each other or spaced apart or separated from each other. For example, in consideration of a design, such as a transfer process requirement, the bank BNK of the 1-1-th sub pixel SP1a and the bank BNK of the 1-2-th sub pixel SP1b in which the same type of micro LED (ED) is disposed may be connected to each other or spaced apart or separated from each other. Further, the bank BNK of the 2-1-th sub pixel SP2a and the bank BNK of the 2-2-th sub pixel SP2b may be connected to each other, spaced apart or separated from each other. The bank BNK of the 3-1-th sub pixel SP3a and the bank BNK of the 3-2-th sub pixel SP3b may be connected to each other, spaced apart or separated from each other. Accordingly, the banks BNK of one pair of first sub pixels SP1, the banks BNK of one pair of second sub pixels SP2, and the banks BNK of third sub pixels SP3 are formed in various forms, but the example embodiments of the present disclosure are not limited thereto.

For example, the plurality of banks BNK may be formed of an organic insulating material. The plurality of banks BNK is configured by a single layer or a double layer of an organic insulating material. For example, the plurality of banks BNK is configured by a photo resist, polyimide (PI), or acrylic-based material, but the example embodiments of the present disclosure are not limited thereto.

The first electrode CE1 may be disposed in each of the plurality of sub pixels. The first electrode CE1 may be disposed on the bank BNK. The first electrode CE1 may be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TL4. A part of the first electrode CE1 of the 3-1-th sub pixel SP3a extends to one area of the 3-1-th sub pixel SP3a to be electrically connected to the fifth signal line TL5. A part of the first electrode CE1 of the 3-2-th sub pixel SP3b extends to the other area of the 3-2-th sub pixel SP3b to be electrically connected to the sixth signal line TL6.

The first electrode CE1 is electrically connected to the anode electrode 134 of the micro LED (ED) and may transmit an anode voltage from the pixel driving circuit PD to the micro LED (ED) through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the example embodiments of the present disclosure are not limited thereto.

The first electrode CE1 may be configured by a conductive material. For example, the first electrode CE1 may be integrally configured with the plurality of signal lines TL. For example, the first electrode CE1 may be configured by the same or substantially same conductive material as the plurality of signal lines TL, but the example embodiments of the present disclosure are not limited thereto. For example, the first electrode CE1 may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the first electrode CE1 may be configured by a multi-layered structure of conductive materials. For example, the plurality of first electrodes CE1 may be configured by a multi-layered structure of titanium (Ti)/aluminum (Al)/titanium (Ti)/indium tin oxide (ITO), but the example embodiments of the present disclosure are not limited thereto.

The micro LED (ED) may be disposed in each of the plurality of sub pixels. The plurality of micro LEDs (ED) may be disposed on the bank BNK and the first electrode CE1. The plurality of micro LEDs (ED) is disposed on the first electrode CE1 and is electrically connected to the first electrode CE1. Accordingly, the micro LED (ED) is applied with an anode voltage from the pixel driving circuit PD through the signal line TL and the first electrode CE1 to emit light.

The plurality of micro LEDs (ED) may include a first micro LED 130, a second micro LED 140, and a third micro LED 150. The first micro LED 130 may be disposed in the first sub pixel SP1. The second micro LED 140 may be disposed in the second sub pixel SP2. The third micro LED 150 may be disposed in the third sub pixel SP3. For example, any one of the first micro LED 130, the second micro LED 140, and the third micro LED 150 is a red micro LED, another is a green micro LED, and the third is a blue micro LED, but the example embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the example embodiments of the present disclosure are not limited thereto.

The first micro LED 130 may include a 1-1-th micro LED 130a disposed in the 1-1-th sub pixel SP1a and a 1-2-th micro LED 130b disposed in the 1-2-th sub pixel SP1b. The second micro LED 140 may include a 2-1-th micro LED 140a disposed in the 2-1-th sub pixel SP2a and a 2-2-th micro LED 140b disposed in the 2-2-th sub pixel SP2b. The third micro LED 150 includes a 3-1-th micro LED 150a disposed in the 3-1-th sub pixel SP3a and a 3-2-th micro LED 150b disposed in the 3-2-th sub pixel SP3b.

At this time, each of the plurality of pixels PX may include at least one first micro LEDs 130. The plurality of pixels PX may include a pixel PX including only a 1-1-th micro LED 130a, a pixel PX including only a 1-2-th micro LED 130b, and a pixel PX including both the 1-1-th micro LED 130a and the 1-2-th micro LED 130b. For example, in some pixel PX among the plurality of pixels PX, only the 1-1-th micro LED 130a may be disposed in a 1-1-th sub pixel SP1a. In another pixel PX among the plurality of pixels PX, only the 1-2-th micro LED 130b may be disposed in a 1-2-th sub pixel SP1b. In the other pixel PX among the plurality of pixels PX, the 1-1-th micro LED 130a and the 1-2-th micro LED 130b may be disposed in both the 1-1-th sub pixel SP1a and the 1-2-th sub pixel SP1b. Accordingly, in some pixel PX, only any one of the 1-1-th micro LED 130a and the 1-2-th micro LED 130b may be disposed and in the other pixel PX, both the 1-1-th micro LED 130a and the 1-2-th micro LED 130b may be disposed.

Each of the plurality of pixels PX may include at least one second micro LEDs 140. The plurality of pixels PX may include a pixel PX including only a 2-1-th micro LED 140a, a pixel PX including only a 2-2-th micro LED 140b, and a pixel PX including both the 2-1-th micro LED 140a and the 2-2-th micro LED 140b. For example, in some pixel PX among the plurality of pixels PX, only the 2-1-th micro LED 140a may be disposed in a 2-1-th sub pixel SP2a. In another pixel PX among the plurality of pixels PX, only the 2-2-th micro LED 140b may be disposed in a 2-2-th sub pixel SP2b. In the other pixel PX among the plurality of pixels PX, the 2-1-th micro LED 140a and the 2-2-th micro LED 140b may be disposed in both the 2-1-th sub pixel SP2a and the 2-2-th sub pixel SP2b. Accordingly, in some pixel PX, only any one of the 2-1-th micro LED 140a and the 2-2-th micro LED 140b may be disposed and in the other pixel PX, both the 2-1-th micro LED 140a and the 2-2-th micro LED 140b may be disposed.

Likewise, each of the plurality of pixels may include at least one third micro LEDs 150. The plurality of pixels PX includes a pixel PX including only a 3-1-th micro LED 150a, a pixel PX including only a 3-2-th micro LED 150b, and a pixel PX including both the 3-1-th micro LED 150a and the 3-2-th micro LED 150b. For example, in some pixel PX among the plurality of pixels PX, only the 3-1-th micro LED 150a may be disposed in a 3-1-th sub pixel SP3a. In another pixel PX among the plurality of pixels PX, only the 3-2-th micro LED 150b may be disposed in a 3-2-th sub pixel SP3b. In the other pixel PX among the plurality of pixels PX, the 3-1-th micro LED 150a and the 3-2-th micro LED 150b may be disposed in both the 3-1-th sub pixel SP3a and the 3-2-th sub pixel SP3b. Accordingly, in some pixel PX, only any one of the 3-1-th micro LED 150a and the 3-2-th micro LED 150b may be disposed and in the other pixel PX, both the 3-1-th micro LED 150a and the 3-2-th micro LED 150b may be disposed.

In the meantime, when the micro LED (ED) is used, a plurality of micro LEDs is formed on a wafer and the micro LED is transferred onto the substrate 110 of the display panel 100 to manufacture the display panel 100. However, during the process of transferring the plurality of micro LEDs (ED) having a micro size from the wafer to the substrate 110, various defects may be caused. For example, in some sub pixel, a non-transfer defect in which the micro LED is not transferred may occur and in the other sub pixel, a defect that the micro LED (ED) is transferred in a wrong position may occur due to the alignment error. Further, even though the transfer process is normally performed, the transferred micro LED (ED) itself may be defective. Accordingly, in consideration of the defects during the transfer process of the plurality of micro LEDs (ED), after transferring the micro LED into one sub pixel, a lighting test of the micro LED (ED) may be performed. When the initially transferred micro LED (ED) is defective, the micro LED (ED) may be additionally transferred to be used.

For example, the 1-1-th micro LED 130a, the 2-1-th micro LED 140a, and the 3-1-th micro LED 150a are primarily transferred to one pixel PX and defects thereof may be tested.

For example, when all the 1-1-th micro LED 130a, the 2-1-th micro LED 140a, and the 3-1-th micro LED 150a are determined to be normal, the 1-2-th micro LED 130b, the 2-2-th micro LED 140b, and the 3-2-th micro LED 150b are not additionally transferred. For example, among the plurality of pixels PX of FIG. 5, a pixel on the left top and a pixel PX on the right bottom are pixels PX in which all the 1-1-th micro LED 130a, the 2-1-th micro LED 140a, and the 3-1-th micro LED 150a are determined to be normal. Therefore, the additional transfer process is not performed thereon, but only the 1-1-th micro LED 130a, the 2-1-th micro LED 140a, and the 3-1-th micro LED 150a may be disposed.

For example, when the 1-1-th micro LED 130a among the 1-1-th micro LED 130a, the 2-1-th micro LED 140a, and the 3-1-th micro LED 150a is determined to be defective, the 1-2-th micro LED 130b may be additionally transferred to one pixel PX. For example, a pixel on the left bottom among the plurality of pixels PX of FIG. 5 and a pixel PX of FIG. 6 are pixels in which all the 1-1-th micro LED 130a, the 2-1-th micro LED 140a, and the 3-1-th micro LED 150a are determined to be defective. Therefore, the 1-2-th micro LED 130b, the 2-2-th micro LED 140b, and the 3-2-th micro LED 150b may be further transferred to the pixel PX.

As still another example, when any one of the 1-1-th micro LED 130a, the 2-1-th micro LED 140a, and the 3-1-th micro LED 150a is not transferred, the same type of micro LED (ED) as the non-transferred micro LED (ED) may be additionally transferred. For example, when as in the pixel PX on the left top, among the plurality of pixels PX of FIG. 5, the 2-1-th micro LED 140a is not transferred, the 2-2-th micro LED 140b may be additionally transferred to the pixel PX.

In summary, a pixel PX in which all the 1-1-th micro LED 130a, the 2-1-th micro LED 140a, and the 3-1-th micro LED 150a which are initially transferred are normal may include only the 1-1-th micro LED 130a, the 2-1-th micro LED 140a, and the 3-1-th micro LED 150a. A pixel PX in which any one of the 1-1-th micro LED 130a, the 2-1-th micro LED 140a, and the 3-1-th micro LED 150a which are initially transferred is defective may further include any one of the 1-2-th micro LED 130b, the 2-2-th micro LED 140b, and the 3-2-th micro LED 150b. Finally, a pixel PX in which any one of the 1-1-th micro LED 130a, the 2-1-th micro LED 140a, and the 3-1-th micro LED 150a is not transferred may further include any one of the 1-2-th micro LED 130b, the 2-2-th micro LED 140b, and the 3-2-th micro LED 150b.

Accordingly, even though the plurality of same type micro LEDs (ED) is transferred to one pixel PX, finally only one micro LED (ED) may be used depending on whether there is a defect. In this case, any one of one pair of micro LEDs (ED) is a main (or primary) micro LED (ED) and the other micro LED (ED) may be a redundancy micro LED (ED). The redundancy micro LED (ED) may be an extra micro LED (ED) which is transferred to prepare for a defect of the main micro LED (ED). When the main micro LED (ED) is defective, the redundancy micro LED (ED) may be used instead. When the main micro LED (ED) is defective, the redundancy micro LED (ED) is additionally transferred to minimize or reduce the degradation of the display quality due to the defect of the main micro LED (ED). For example, the 1-1-th micro LED 130a, the 2-1-th micro LED 140a, and the 3-1-th micro LED 150a are used as main micro LEDs (ED) and the 1-2-th micro LED 130b, the 2-2-th micro LED 140b, and the 3-2-th micro LED 150b may be used as redundancy micro LEDs (ED). Accordingly, the redundancy micro LED (ED) is selectively transmitted only to the pixel PX in which a defect occurs so that the number of redundancy micro LEDs (ED) is reduced and a manufacturing cost is saved.

Referring to FIGS. 5 to 7 together, the second electrode CE2 may be disposed in each of the plurality of sub pixels. The second electrode CE2 may be disposed on the micro LED (ED). The second electrode CE2 may be electrically connected to the pixel driving circuit PD through the plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage may be applied to the second electrodes CE2 of the plurality of sub pixels. For example, the same voltage may be applied to the second electrode CE2 of each of the plurality of sub pixels and the cathode electrode 135 of the micro LED (ED). Therefore, the second electrode CE2 may be a common electrode, but the example embodiments of the present disclosure are not limited thereto.

At least some of the plurality of sub pixel may share the second electrode CE2. At least some of the second electrodes CE2 of the plurality of sub pixels may be electrically connected to each other. As the same voltage is applied to the second electrode CE2, the second electrodes CE2 of at least some of sub pixels are shared. For example, the second electrodes of at least some pixels PX, among the plurality of pixels PX disposed on the same row may be connected to each other. For example, one second electrode CE2 may be disposed in the plurality of pixels PX. One second electrode CE2 may be disposed in every n sub pixels.

For example, some of the second electrodes CE2 of the plurality of sub pixels may be spaced apart or separated from each other. For example, a second electrode CE2 connected to pixels PX in a n-th row and a second electrode CE2 connected to pixels PX in a n+1-th row may be spaced apart or separated from each other. For example, the plurality of second electrodes CE2 may be disposed to be spaced apart from each other with the plurality of communication lines NL extending in the row direction therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 may be disposed on the substrate 110, but the example embodiments of the present disclosure are not limited thereto.

The plurality of second electrodes CE2 may be configured by a transparent conductive material, but the example embodiments of the present disclosure are not limited thereto. The plurality of second electrodes CE2 is configured by a transparent conductive material so that light emitted from the micro LED (ED) may travel toward the top of the second electrode CE2. For example, the second electrode CE2 may be configured by a transparent conductive material, such as indium tin oxide (ITO), indium zinc oxide (IZO), indium gallium zinc oxide (IGZO), but the example embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

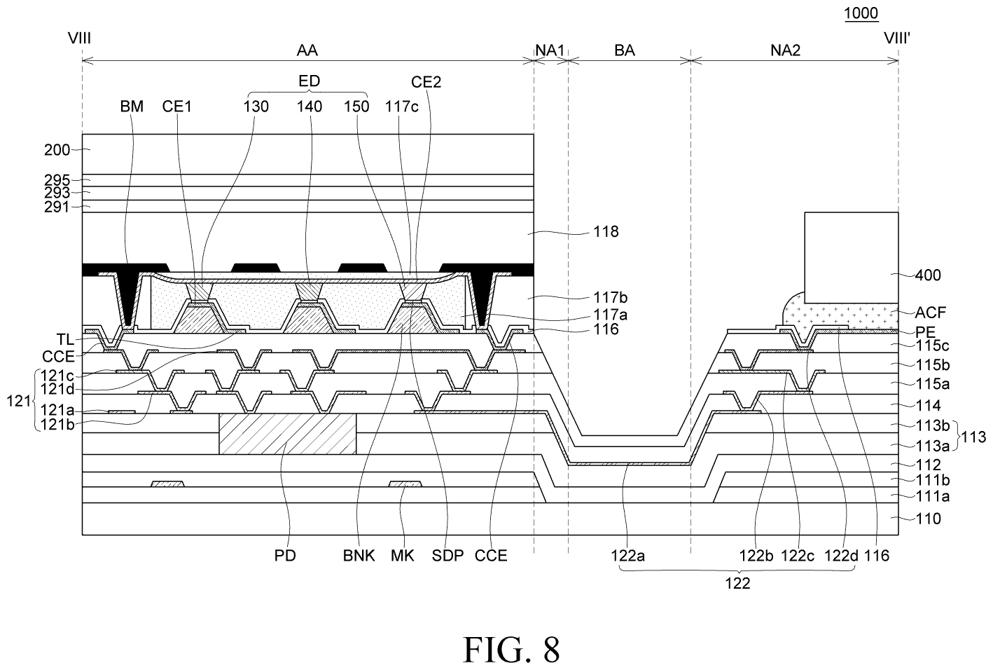

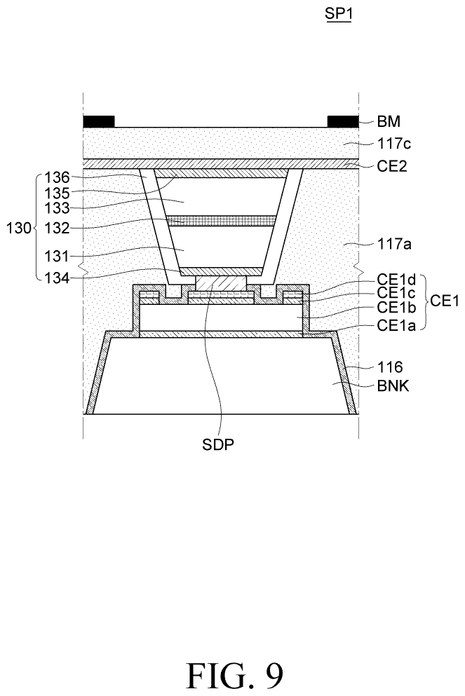

Hereinafter, a cross-sectional structure of a sub pixel of the display panel 100 according to the example embodiment of the present disclosure will be described with reference to FIGS. 8 and 9.

FIG. 8 is a cross-sectional view of a display device according to an example embodiment of the present disclosure; FIG. 9 is a cross-sectional view of a display device according to an example embodiment of the present disclosure; For example, FIG. 8 is a cross-sectional view taken along VIII-VIII′ of FIG. 3 which is a cross-sectional view of an active area AA, a first non-active area NA1, a bending area BA, and a second non-active area NA2. For example, FIG. 9 is an enlarged cross-sectional view of a first sub pixel SP1.

Referring to FIG. 8, a first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or a plurality of layers of silicon oxide (SiOx) or silicon nitride (SiNx), but the example embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize or reduce cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display device 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the example embodiments of the present disclosure are not limited thereto.

The pixel driving circuit PD may be disposed on the adhesive layer 112 in the active area AA. When the pixel driving circuit PD is implemented as a driving driver, the driving driver may be mounted on the adhesive layer 112 by the transfer process, but the example embodiments of the present disclosure are not limited thereto.

A protection layer 113 may be disposed on the adhesive layer 112 and the pixel driving circuit PD. The protection layer 113 may be disposed so as to enclose the pixel driving circuit PD, but the example embodiments of the present disclosure are not limited thereto. For example, the protection layer 113 may be disposed so as to cover at least a part of a side surface of the pixel driving circuit PD. As another example, the protection layer 113 may be disposed so as to cover at least a part of a top surface of the pixel driving circuit PD.

The protection layer 113 may include one or more organic insulating layers. For example, the protection layer 113 may include a first protection layer 113a disposed on the adhesive layer 112 and a second protection layer 113b disposed on the first protection layer 113a. For example, the first protection layer 113a and the second protection layer 113b may be disposed so as to enclose a side surface of the pixel driving circuit PD. For example, the second protection layer 113b may be disposed so as to cover at least a part of a top surface of the pixel driving circuit PD. For example, at least one of the first protection layer 113a and the second protection layer 113b of the protection layer 113 disposed on the bending area BA may be omitted. For example, the first protection layer 113a is entirely disposed in the active area AA and the non-active area NA and the second protection layer 113b may be partially disposed in the active area AA, the first non-active area NA1, and the second non-active area NA2. For example, a part of the second protection layer 113b in the bending area BA may be removed. However, the protection layer 113 may be formed by a single layer, but the example embodiments of the present disclosure are not limited thereto.

Each of the first protection layer 113a and the second protection layer 113b of the protection layer may be configured by an organic insulating material, but the example embodiments of the present disclosure are not limited thereto. For example, the first protection layer 113a and the second protection layer 113b may be configured by a photo resist, polyimide (PI), or photo acrylic-based material, but the example embodiments of the present disclosure are not limited thereto. For example, the first protection layer 113a and the second protection layer 113b may be an over coating layer or an insulating layer, but the example embodiments of the present disclosure are not limited thereto.

According to one or more aspects of the present disclosure, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, and a 1-4-th connection line 121d, but the example embodiments of the present disclosure are not limited thereto.

For example, the plurality of 1-1-th connection lines 121a may be disposed on the second protection layer 113b. The plurality of 1-1-th connection lines 121a may be electrically connected to the pixel driving circuit PD. The plurality of 1-1-th connection lines 121a may transmit a voltage output from the pixel driving circuit PD to the first electrode CE1 or the second electrode CE2.

For example, an additional protection layer may be further disposed on the second protection layer 113b. For example, a third protection layer 114 may be further disposed on the second protection layer 113b. The third protection layer 114 may be entirely disposed in the active area AA and the non-active area NA. In the bending area BA, the third protection layer 114 may cover a side surface of the second protection layer 113b and the top surface of the first protection layer 113a. The third protection layer 114 may be configured by an organic insulating material. For example, the third protection layer 114 may be configured by a photo resist, polyimide (PI), or photo acrylic-based material, but the example embodiments of the present disclosure are not limited thereto. For example, the first protection layer 113a, the second protection layer 113b, and the third protection layer 114 may be configured by the same or substantially same material, but the example embodiments of the present disclosure are not limited thereto.

The plurality of 1-2-th connection lines 121b may be disposed on the third protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the third protection layer 114. The other part of the 1-2-th connection line 121b may be electrically connected to the 1-1-th connection line 121a through the contact hole of the third protection layer 114. However, the example embodiments of the present disclosure are not limited thereto. A voltage output from the pixel driving circuit PD may be transmitted to the first electrode CEL or the second electrode CE2 through a connection line other than the plurality of 1-2-th connection lines 121b.

The first insulating layer 115a may be disposed on the plurality of 1-2-th connection lines 121b. The first insulating layer 115a may be entirely disposed in the active area AA and the non-active area NA, but the example embodiments of the present disclosure are not limited thereto. The first insulating layer 115a may be configured by an organic insulating material, but the example embodiments of the present disclosure are not limited thereto. For example, the first insulating layer 115a may be configured by a photo resist, polyimide (PI), or photo acrylic-based material, but the example embodiments of the present disclosure are not limited thereto.

The plurality of 1-3-th connection lines 121c may be disposed on the first insulating layer 115a. The plurality of 1-3-th connection lines 121c may be electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b may be disposed on the plurality of 1-3-th connection lines 121c. The second insulating layer 115b may be disposed in a remaining area excluding the bending area BA, but the example embodiments of the present disclosure are not limited thereto. The second insulating layer 115b may be disposed in the active area AA, the first non-active area NA1, and the second non-active area NA2, but the example embodiments of the present disclosure are not limited thereto. For example, a part of the second insulating layer 115b disposed in the bending area BA may be removed. The second insulating layer 115b may be configured by an organic insulating material, but the example embodiments of the present disclosure are not limited thereto. For example, the second insulating layer 115b is configured by a photo resist, polyimide (PI), or photo acrylic-based material, but the example embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3-th connection lines 121c. For example, the 1-4-th connection lines 121d may be electrically connected to the 1-3-th connection line 121c through a contact hole of the second insulating layer 115b.

According to one or more aspects of the present disclosure, in the non-active area NA, the plurality of second connection lines 122 may be disposed on the second protection layer 113b. The plurality of second connection lines 122 may be wiring lines which transmit a signal transmitted from the flexible circuit board (or flexible film) 400 and the printed circuit board 160 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) 400 and the printed circuit board 500.

For example, the plurality of second connection lines 122 extends toward the active area AA from the pad unit PAD to transmit a signal to the wiring line of the active area AA. In this case, the plurality of second connection lines 122 may serve as a link line LL. The plurality of second connection lines 122 may include a 2-1-th connection lines 122a, a 2-2-th connection lines 122b, a 2-3-th connection lines 122c, and a 2-4-th connection lines 122d.

The plurality of 2-1-th connection lines 122a may be disposed on the second protection layer 113b. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) 400 and the printed circuit board 500 to the pad unit PAD to the pixel driving circuit PD of the active area AA. For example, the 2-1-th connection line 122a extends from the second non-active area NA2 to the first non-active area NA1 and may be electrically connected to any one of the 1-1-th connection line 121a, the 1-2-th connection line 121b, the 1-3-th connection line 121c, and the 1-4-th connection line 121d of the plurality of first connection lines 121. For example, the 2-1-th connection line 122a may be directly connected to the 1-1-th connection line 121a disposed on the same layer or may be connected to the 1-2-th connection line 121b disposed on a different layer through a contact hole of the third protection layer 114, but is not limited thereto.

The plurality of 2-2-th connection lines 122b may be disposed on the third protection layer 114. The plurality of 2-2-th connection lines 122b may be disposed in the second non-active area NA2. The 2-2-th connection line 122b may be electrically connected to the 2-1-th connection line 122a through the contact hole of the third protection layer 114. Accordingly, a signal from the flexible circuit board (or flexible film) 400 and the printed circuit board 500 may be transmitted to the 2-1-th connection line 122a through the 2-2-th connection line 122b.

The 2-3-th connection lines 122c may be disposed on the first insulating layer 115a. The 2-3-th connection lines 122c may be disposed in the second non-active area NA2. The 2-3-th connection lines 122c may be electrically connected to the 2-2-th connection line 122b through a contact hole of the first insulating layer 115a. Accordingly, a signal from the flexible circuit board (or flexible film) 400 and the printed circuit board 500 may be transmitted to the 2-1-th connection line 122a through the 2-3-th connection line 122c and the 2-2-th connection line 122b.

The 2-4-th connection lines 122d may be disposed on the second insulating layer 115b. The 2-4-th connection lines 122d may be disposed in the second non-active area NA2. The 2-4-th connection lines 122d may be electrically connected to the 2-3-th connection line 122c through a contact hole of the second insulating layer 115b. Accordingly, a signal from the flexible circuit board (or flexible film) 400 and the printed circuit board 500 may be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may be configured by a conductive material having excellent ductility, such as gold (Au), silver (Ag), or aluminum (Al), but the example embodiments of the present disclosure are not limited thereto. As another example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the example embodiments of the present disclosure are not limited thereto. The third insulating layer 115c may be disposed in the active area AA, the first non-active area NA1, and the second non-active area NA2. A part of the third insulating layer 115c disposed in the bending area BA may be removed. The third insulating layer 115c may be configured by an organic insulating material, but the example embodiments of the present disclosure are not limited thereto. For example, the third insulating layer 115c may be configured by a photo resist, polyimide (PI), or photo acrylic-based material, but the example embodiments of the present disclosure are not limited thereto.

A plurality of banks BNK may be disposed on the third insulating layer 115c in the active area AA. The plurality of banks BNK may be disposed so as to overlap each of the plurality of sub pixels. One or more same type micro LED (ED) may be disposed above each of the plurality of banks BNK.

A plurality of signal lines TL may be disposed on the third insulating layer 115c in the active area AA. The plurality of signal lines TL may be disposed in an area between the plurality of banks BNK. For example, the plurality of signal lines TL may be disposed to be adjacent to any one of the plurality of banks BNK.

A plurality of contact electrodes CCE may be disposed on the third insulating layer 115c in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of the bank BNK from the adjacent signal line TL. The first electrode CE1 may be disposed on the top surface of the bank BNK and the side surface of the bank BNK. For example, the first electrode CE1 may be disposed to extend from the signal line TL on the top surface of the third insulating layer 115c to the side surface of the bank BNK and the top surface of the bank BNK.

Referring to FIG. 9, the first electrode CE1 may be configured by a plurality of conductive layers. For example, the first electrode CE1 may include a first conductive layer CE1a, a second conductive layer CE1b, a third conductive layer CE1c, and a fourth conductive layer CE1d, but the example embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may be configured by titanium (Ti), molybdenum (Mo), aluminum (Al), or titanium (Ti) and indium tin oxide (ITO), but the example embodiments of the present disclosure are not limited thereto.

According to one or more aspects of the present disclosure, some conductive layer having a good reflection efficiency, among a plurality of conductive layers which configures the first electrode CE1 may be configured as an alignment key for alignment of the micro LED (ED) and/or a reflective plate. For example, the second conductive layer CE1b, among the plurality of conductive layers of the first electrode CE1, may include a reflective material. For example, the second conductive layer CE1b may include aluminum (Al), but the example embodiments of the present disclosure are not limited thereto. Therefore, the second conductive layer CE1b may be configured as a reflective plate. Further, the second conductive layer CE1b has a high reflection efficiency to be easily identified during the manufacturing process so that a position of the micro LED (ED) or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed remains and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to one or more aspects of the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which is adhesive to the solder pattern SPD, and has corrosion resistance and acid resistance. However, the example embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, the example embodiments of the present disclosure are not limited thereto.

According to one or more aspects of the present disclosure, the signal line TL, the contact electrode CCE, and the pad electrode PE disposed on the same layer as the first electrode CE1 may be configured by a plurality of layers of conductive materials, but the example embodiment of the present disclosure are not limited thereto. For example, the signal line TL, the contact electrode CCE, and the pad electrode PE may be formed of a plurality of layers of indium tin oxide (ITO)/titanium (Ti)/aluminum (Al)/titanium (Ti), but the example embodiments of the present disclosure are not limited thereto.

According to one or more aspects of the present disclosure, in each of the plurality of sub pixels, the solder pattern SDP may be disposed on the first electrode CE1. The solder pattern SDP may bond the micro LED (ED) to the first electrode CE1. The solder pattern SDP may bond the first electrode CE1 and the anode electrode 134 of the micro LED (ED) to be electrically connected to each other. The first electrode CE1 and the micro LED (ED) may be electrically connected through eutectic bonding using the solder pattern SDP, but the example embodiments of the present disclosure are not limited thereto. For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) may be bonded to the solder pattern SDP and the first electrode CE1 using the eutectic bonding without a separate adhesive material. For example, the solder pattern SDP may be configured by indium (Id), tin (Sn), or an alloy thereof, but the example embodiments of the present disclosure are not limited thereto. For example, the solder pattern SDP may be a bonding pad or an adhesive pad, but the example embodiments of the present disclosure are not limited thereto.

According to one or more aspects of the present disclosure, the passivation layer 116 may be disposed on the plurality of signal lines TL, the plurality of first electrodes CE1, the plurality of contact electrodes CCE, and the third insulating layer 115c. For example, the passivation layer 116 may be disposed in the active area AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 may be configured by a single layer or a plurality of layers of silicon oxide (SiOx) or silicon nitride (SiNx), but the example embodiments of the present disclosure are not limited thereto. For example, the passivation layer 116 may be a protection layer or an insulating layer, but the example embodiments of the present disclosure are not limited thereto. For example, the passivation layer 116 may include a hole through which the solder pattern SDP is exposed.

In each of the plurality of sub pixels, the micro LED (ED) may be disposed on the solder pattern SDP. A first micro LED 130 may be disposed in the first sub pixel SP1. A second micro LED 140 may be disposed in the second sub pixel SP2. A third micro LED 150 may be disposed in the third sub pixel SP3.

The micro LED (ED) may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the example embodiments of the present disclosure are not limited thereto.

Referring to FIG. 9, the first micro LED 130 may include an anode electrode 134, a first semiconductor layer 131, an active layer 132, a second semiconductor layer 133, a cathode electrode 135, and an encapsulation film 136, but the example embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 is an n-type impurity doped semiconductor layer and the other one is a p-type impurity doped semiconductor, but the example embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the example embodiments of the present disclosure are not limited thereto. For example, the n-type impurity may be silicon (Si), germanium (Ge), selenium (Se), carbon (C), tellurium (Te), or tin (Sn), but the example embodiments of the present disclosure are not limited thereto. For example, the p-type impurity may be magnesium (Mg), zinc (Zn), calcium (Ca), strontium (Sr), barium (Ba), or beryllium (Be), but the example embodiments of the present disclosure are not limited thereto.

For example, each the first semiconductor layer 131 and the second semiconductor layer 133 may be a nitride semiconductor including an n-type impurity or a nitride semiconductor including a p-type impurity, but the example embodiments of the present disclosure are not limited thereto. For example, the first semiconductor layer 131 may be a nitride semiconductor including a p-type impurity and the second semiconductor layer 133 may be a nitride semiconductor including an n-type impurity, but the example embodiments of the present disclosure are not limited thereto.

The active layer 132 may be disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured by one of a single well structure, a multi-well structure, a signal quantum well structure, a multi-quantum well (MQC) structure, a quantum dot structure, and a quantum line structure, but the example embodiments of the present disclosure are not limited thereto. For example, the active layer 132 may be configured by indium gallium nitride (InGaN) or gallium nitride (GaN), but the example embodiments of the present disclosure are not limited thereto.

As another example, the active layer 132 has a multi quantum well (MQW) structure having a well layer and a barrier layer with a band gap higher than the well layer. For example, in the active layer 132, InGaN is configured as a well layer and an AlGaN layer is configured as a barrier layer, but the example embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be configured by a conductive material which may form eutectic bonding with the solder pattern SDP, but the example embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the example embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be configured by a transparent conductive material to allow light emitted from the micro LED (ED) to be directed to the top of the micro LED (ED), but the example embodiments of the present disclosure are not limited thereto. For example, the cathode electrode 135 may be configured by a material, such as indium tin oxide (ITO), indium zinc oxide (IZO), indium gallium zinc oxide (IGZO), but the example embodiments of the present disclosure are not limited thereto.

The encapsulation film 136 may be disposed in at least a part of the first semiconductor layer 131, the active layer 132, the second semiconductor layer 133, the anode electrode 134, and the cathode electrode 135. For example, the encapsulation film 136 may enclose at least a part of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP may be connected. For example, at least a part of the cathode electrode 135 is exposed from the encapsulation film 136 so that the cathode electrode 135 and the second electrode CE2 may be connected. For example, the encapsulation film 136 may be formed of an insulating material, such as silicon nitride (SiNx) or silicon oxide (SiOx), but the example embodiments of the present disclosure are not limited thereto.

As another example, the encapsulation film 136 may have a structure in which a reflective material is dispersed in a resin layer, but the example embodiments of the present disclosure are not limited thereto. For example, the encapsulation film 136 may be manufactured with reflectors with various structures, but the example embodiments of the present disclosure are not limited thereto. Light emitted from the active layer 132 is upwardly reflected by the encapsulation film 136 so that light extraction efficiency may be improved. For example, the encapsulation film 136 may be a reflective layer, but the example embodiments of the present disclosure are not limited thereto.

According to one or more aspects of the present disclosure, it is described that the micro LED (ED) has a vertical structure, but the example embodiments of the present disclosure are not limited thereto. For example, the micro LED (ED) may have a lateral structure or a flip-chip structure.

The first micro LED 130 has been described with reference to FIG. 9 and the second micro LED 140 and the third micro LED 150 may have the substantially same structure as the first micro LED 130. For example, the second micro LED 140 and the third micro LED 150 may be substantially the same as the first semiconductor layer 131, the active layer 132, the second semiconductor layer 133, the anode electrode 134, the cathode electrode 135, and the encapsulation film 136 of the first micro LED 130.

According to one or more aspects of the present disclosure, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover the bank BNK, a part of the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a extends in a row direction and may be spaced apart from each other in a column direction. For example, the first optical layer 117a may be disposed so as to enclose side portions of the micro LED (ED) and the bank BNK between the passivation layer 116 and the second electrode CE2, but the example embodiments of the present disclosure are not limited thereto. For example, the first optical layer 117a may be a diffusion layer or a side wall diffusion layer, but the example embodiments of the present disclosure are not limited thereto.

The first optical layer 117a may include an organic insulating material in which micro particles are dispersed, but the example embodiments of the present disclosure are not limited thereto. For example, the first optical layer 117a may be configured by siloxane in which micro metal particles, such as titanium dioxide (TiO2) particles, are dispersed, but the example embodiments of the present disclosure are not limited thereto. Light from the plurality of micro LEDs (ED) is scattered by micro particles dispersed in the first optical layer 117a to be emitted to the outside of the display device 1000. Accordingly, the first optical layer 117a may improve extraction efficiency of light emitted from the plurality of micro LEDs (ED).

For example, the first optical layer 117a may be disposed in each of the plurality of pixels PX or disposed in some pixel PX disposed in the same row together, but the example embodiments of the present disclosure are not limited thereto. For example, the first optical layer 117a is disposed in each of the plurality of pixels PX or the plurality of pixels PX may share one first optical layer 117a. As another example, each of the plurality of sub pixels separately includes the first optical layer 117a, but the example embodiments of the present disclosure are not limited thereto.

According to one or more aspects of the present disclosure, in the active area AA, a second optical layer 117b may be disposed on the passivation layer 116. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. However, the example embodiments of the present disclosure are not limited thereto. For example, the second optical layer 117b may be a diffusion layer, a diffusion window, or a window diffusion layer, but the example embodiments of the present disclosure are not limited thereto.

The second optical layer 117b may be configured by an organic insulating material, but the example embodiments of the present disclosure are not limited thereto. The second optical layer 117b may be configured by the same or substantially same material as the first optical layer 117a, but the example embodiments of the present disclosure are not limited thereto. For example, the first optical layer 117a may include micro particles, but the second optical layer 117b does not include micro particles. For example, the second optical layer 117b is configured by siloxane, but the example embodiments of the present disclosure are not limited thereto.

For example, a thickness of the first optical layer 117a may be smaller than a thickness of the second optical layer 117b, but the example embodiments of the present disclosure are not limited thereto. Accordingly, in the plan view, an area in which the first optical layer 117a is disposed may include a concave portion which is inwardly dented from an upper surface of the second optical layer 117b.

According to one or more aspects of the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of micro LEDs (ED). For example, the second electrode CE2 may include a transparent conductive oxide, such as indium tin oxide (ITO) or indium zinc oxide (IZO), but the example embodiments of the present disclosure are not limited thereto. For example, the second electrode CE2 may be disposed to be in contact with the cathode electrode 135. For example, the second electrode CE2 may overlap the first optical layer 117a. For example, the second electrode may cover a plane at the outside of the first optical layer 117a.

The second electrode CE2 may continuously extend in a first direction of the substrate 110. Accordingly, the second electrode may be commonly connected to the plurality of pixels PX disposed in the first direction of the substrate 110. For example, the second electrode CE2 may be commonly connected to the plurality of pixels PX.

According to one or more aspects of the present disclosure, the second electrode CE2 may continuously extend on the first optical layer 117a, the second optical layer 117b, and the micro LED (ED). The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c may be disposed on the second electrode CE2. The third optical layer 117c may be disposed so as to overlap the plurality of micro LEDs (ED) and the first optical layer 117a. The third optical layer 117c is disposed above the second electrode CE2 and the plurality of micro LEDs (ED) so that mura which may be generated in a part of the plurality of micro LEDs (ED) may be improved. For example, when the plurality of micro LEDs (ED) is transferred onto the substrate 110 of the display panel 100, an area in which the interval between the plurality of micro LEDs (ED) is not uniform may be caused due to the process deviation. When the interval between the plurality of micro LEDs (ED) is not uniform, an emission area of each of the plurality of micro LEDs (ED) is not uniformly disposed so that the mura may be visible to a user. Accordingly, the third optical layer 117c which is configured to uniformly diffuse light is configured above the plurality of micro LEDs (ED) so that light emitted from some micro LED (ED) which is visible as mura may be reduced. Accordingly, light emitted from the plurality of micro LEDs (ED) is uniformly diffused by the third optical layer 117c to be extracted to the outside of the display device 1000 so that the luminance uniformity of the display device 1000 may be improved.

The third optical layer 117c may be configured by an organic insulating material in which micro particles are dispersed, but the example embodiments of the present disclosure are not limited thereto. For example, the third optical layer 117c may be configured by siloxane in which micro metal particles, such as titanium dioxide (TiO2) particles, are dispersed, but the example embodiments of the present disclosure are not limited thereto. For example, the third optical layer 117c is configured by the same or substantially same material as the first optical layer 117a, but the example embodiments of the present disclosure are not limited thereto. For example, the third optical layer 117c may be a diffusion layer or a upward diffusion layer, but the example embodiments of the present disclosure are not limited thereto.

According to one or more aspects of the present disclosure, light from the plurality of micro LEDs (ED) is scattered by micro particles dispersed in the third optical layer 117c to be emitted to the outside of the display device 1000. The third optical layer 117c uniformly mixes light emitted from the plurality of micro LEDs (ED) to further improve the luminance uniformity of the display device 1000. Further, the light extraction efficiency of the display device 1000 may be improved by light scattered from the plurality of micro particles so that the display device 1000 may be driven at a low power.

In the active area AA, a black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels may be suppressed.

For example, the black matrix BM may be configured by an opaque material, but the example embodiments of the present disclosure are not limited thereto. For example, the black matrix BM may be configured by an organic insulating material to which black pigment or black dye are added, but the example embodiments of the present disclosure are not limited thereto.

A black matrix BM includes a plurality of transmission holes. The plurality of transmission holes is openings which overlap micro LEDs (ED) of a plurality of sub pixels. Light emitted from the plurality of micro LEDs (ED) may be extracted to the outside of the display panel 100 through the plurality of transmission holes. The plurality of transmission holes may be disposed so as to overlap some sub pixel of the plurality of sub pixels included in one pixel PX.

The plurality of transmission holes may be larger than the plurality of micro LEDs (ED). For example, on the plane, the plurality of transmission holes is formed to be wider than the plurality of micro LEDs (ED) to ensure a margin for a process deviation.

A planar shape of the plurality of transmission holes may correspond to a planar shape of the plurality of micro LEDs (ED). For example, when the planar shape of the plurality of micro LEDs (ED) is a rectangle, the planar shape of the plurality of transmission holes may be a rectangle. However, the planar shape of the plurality of transmission holes and the planar shape of the plurality of micro LEDs (ED) may be different from each other, but are not limited thereto.

A transmission holes of the black matrix BM may be formed in only one of one pair of first sub pixels SP1, one of one pair of second sub pixels SP2, and one of one pair of third sub pixels SP3, which form one pixel PX.

In the active area AA, a cover layer 118 may be disposed on the black matrix BM. The cover layer 118 may protect configurations below the cover layer 118. For example, the cover layer 118 may be configured by an organic insulating material, but the example embodiments of the present disclosure are not limited thereto. For example, the cover layer 118 may be configured by a photo resist, polyimide (PI), or photo acrylic-based material, but the example embodiments of the present disclosure are not limited thereto. For example, the cover layer 118 may be an over coating layer or an insulating layer, but the example embodiments of the present disclosure are not limited thereto.

A polarization layer 293 may be disposed on the cover layer 118 by means of the first adhesive layer 291. A cover member 200 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the example embodiments of the present disclosure are not limited thereto.

According to one or more aspects of the present disclosure, a plurality of pad electrodes PE may be disposed on the third insulating layer 115c in the second non-active area NA2. For example, at least a part of the plurality of pad electrodes PE may be exposed from the passivation layer 116. For example, the plurality of pad electrodes PE may be electrically connected to the 2-4-th connection line 122d through a contact hole of the third insulating layer 115c.

The adhesive layer ACF may be disposed on the plurality of pad electrodes PE. The adhesive layer ACF may be an adhesive layer in which conductive balls are dispersed in an insulating material, but the example embodiments of the present disclosure are not limited thereto. When heat or a pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) 400, the flexible circuit board (or flexible film) 400 may be attached or bonded to the plurality of pad electrodes PE. For example, the adhesive layer ACF may be anisotropic conductive film, but the example embodiments of the present disclosure are not limited thereto.

The flexible circuit board (or flexible film) 400 may be disposed on the adhesive layer ACF. The flexible circuit board (or flexible film) 400 may be electrically connected to the plurality of pad electrodes PE through the adhesive layer ACF. Accordingly, a signal output from the flexible circuit board (or flexible film) 400 and the printed circuit board 500 may be transmitted to the pixel driving circuit PD of the active area AA through the plurality of pad electrodes PE, the 2-4-th connection line 122d, the 2-3-th connection line 122c, the 2-2-th connection line 122b, and the 2-1-th connection line 122a.

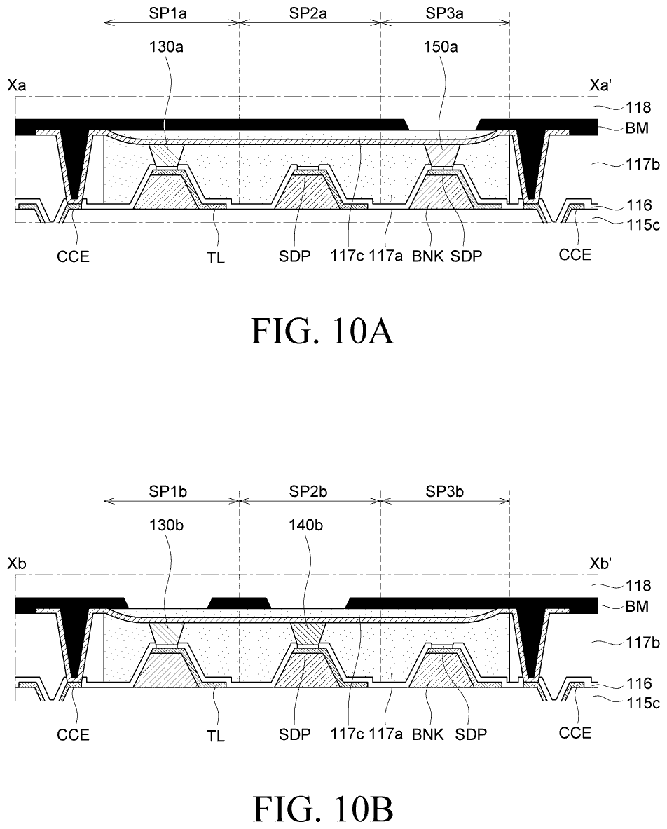

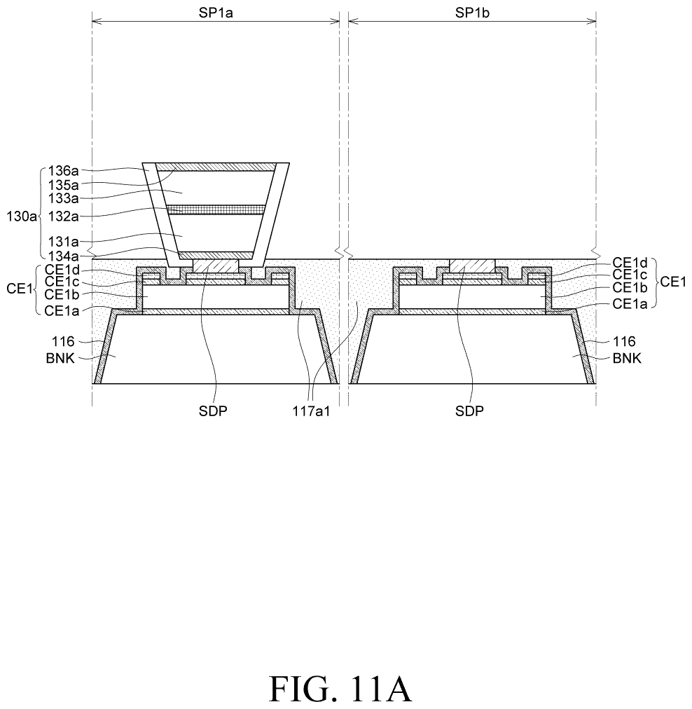

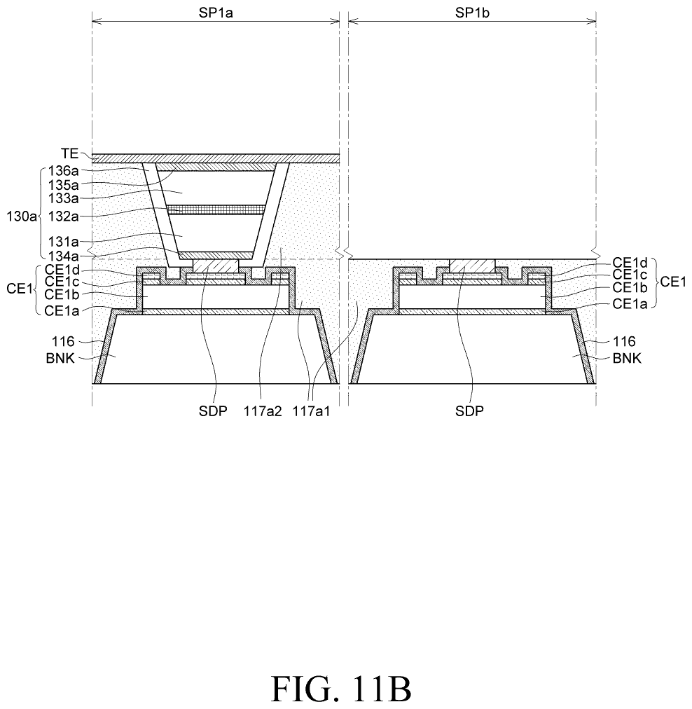

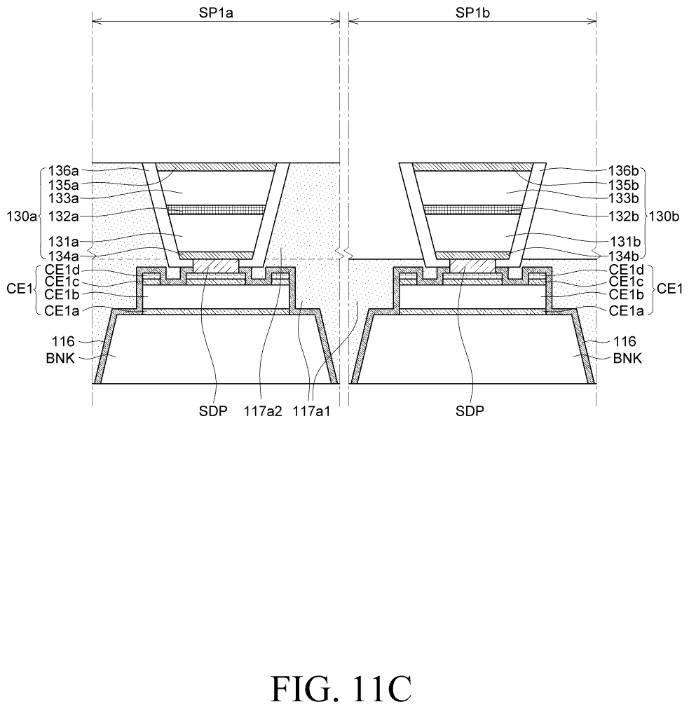

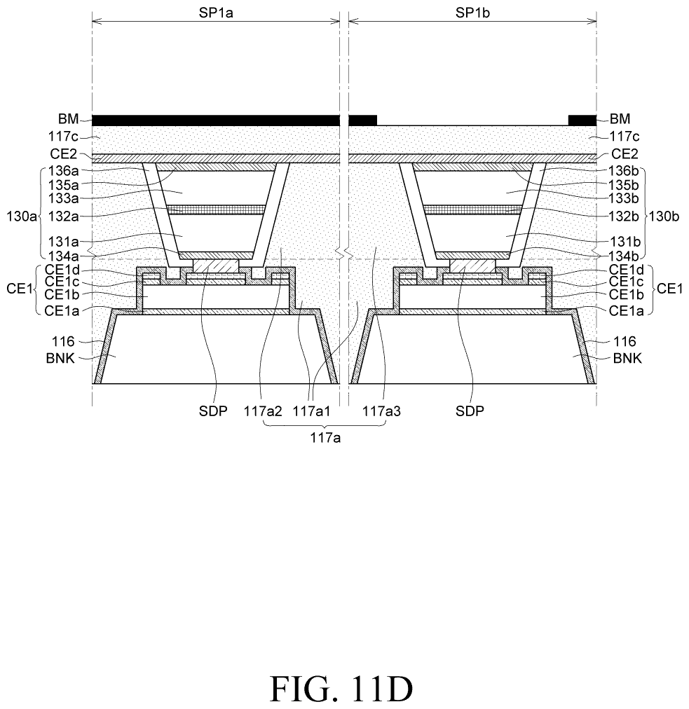

Hereinafter, a repair method of the display device 1000 according to an example embodiment of the present disclosure will be described with reference to FIGS. 10A to 11D.

FIGS. 10A and 10B are cross-sectional views taken X-Xa′ and Xb-Xb′ of FIG. 7 and are cross-sectional views of a display device according to the example embodiment of the present disclosure. FIGS. 11A to 11D are cross-sectional views for explaining a manufacturing process of a display device according to an example embodiment of the present disclosure. For example, FIG. 10A is a schematic cross-sectional view of a 1-1-th sub pixel SP1a, a 2-1-th sub pixel SP2a, and a 3-1-th sub pixel SP3a of a pixel PX on the right top, among the plurality of pixels PX of FIG. 5. FIG. 10B is a schematic cross-sectional view of a 1-2-th sub pixel SP1b, a 2-2-th sub pixel SP2b, and a 3-2-th sub pixel SP3b of a pixel PX on the right top, among the plurality of pixels PX of FIG. 5. FIGS. 11A to 11D are views for explaining a process of repairing a defective sub pixel during a manufacturing process of a display device 1000 and are schematic cross-sectional views of a 1-1-th sub pixel SP1a and a 1-2-th sub pixel SP1b.

Referring to FIGS. 10A and 10B, a main micro LED (ED) may be primarily transferred to the 1-1-th sub pixel SP1a, the 2-1-th sub pixel SP2a, and the 3-1-th sub pixel SP3a, among the plurality of sub pixels which forms one pixel PX. However, when a defect that the main micro LED (ED) is not lit or a non-transferring defect occurs, the redundancy micro LED (ED) may be secondarily transferred to the remaining 1-2-th sub pixel SP1b, 2-2-th sub pixel SP2b, and 3-2-th sub pixel SP3b. In this case, the 1-1-th sub pixel SP1a, the 2-1-th sub pixel SP2a, and the 3-1-th sub pixel SP3a to which the main micro LEDs (ED) are transferred are defined as main sub pixels. The 1-2-th sub pixel SP1b, the 2-2-th sub pixel SP2b, and the 3-2-th sub pixel SP3b to which the redundancy micro LEDs (ED) are transferred may be defined as redundancy sub pixels.

For example, if the 1-1-th sub pixel SP1a to which the 1-1-th micro LED 130a is transferred is defective, the 1-2-th micro LED 130b may be additionally transferred to the 1-2-th sub pixel SP1b which is configured to emit the same color light as the 1-1-th sub pixel SP1a. For example, if the 2-1-th micro LED 140a is not transferred to the 2-1-th sub pixel SP2a, the 2-2-th micro LED 140b may be additionally transferred to the 2-2-th sub pixel SP2b which is configured to emit the same color light as the 2-1-th sub pixel SP2a.

Further, the transmission hole of the black matrix BM may be formed so as to correspond to some sub pixel which is substantially driven, among the plurality of sub pixels included in one pixel PX. For example, in a defective main sub pixel, a transmission hole of the black matrix BM is not formed, but the transmission hole of the black matrix BM may be formed in the redundancy sub pixel corresponding to the defective main sub pixel.

For example, referring to FIG. 10A, when the 1-1-th sub pixel SP1a and the 2-1-th sub pixel SP2a, among the main sub pixels, are determined to be defective and the 3-1-th sub pixel SP3a is determined to be normal, a transmission hole which overlaps the 3-1-th micro LED 150a may be formed in the black matrix BM of the 3-1-th sub pixel SP3a. Further, a transmission hole is not formed in the black matrix of the 1-1-th sub pixel SP1a and the 2-1-th sub pixel SP2a and the black matrix BM may be disposed so as to entirely cover the 1-1-th sub pixel SP1a and the 2-1-th sub pixel SP2a. For example, referring to FIG. 10B, in the black matrix BM of the 1-2-th sub pixel SP1b and the 2-2-th sub pixel SP2b in which the redundancy micro LED (ED) is additionally transferred, a transmission hole which overlaps the redundancy micro LED (ED) may be formed. Further, in the black matrix BM of the 3-2-th sub pixel SP3b to which the redundancy micro LED (ED) is not transferred, the transmission hole is not formed. Accordingly, the plurality of transmission holes of the black matrix BM may be disposed so as to overlap some main micro LED (ED) which is normally driven, among the plurality of main micro LEDs (ED). Further, the plurality of transmission holes of the black matrix BM may be disposed so as to overlap all the plurality of redundancy micro LEDs (ED) which is additionally transferred.

Hereinafter, a repair method of additionally transferring a redundancy micro LED (ED) when a sub pixel including a main micro LED (ED) is defective will be described with reference to FIGS. 11A to 11D.

Referring to FIG. 11A, on a display panel 100 on which a bank BNK, a first electrode CE1, a passivation layer 116, and a solder pattern SDP are formed on the substrate 110, a part of the first optical layer 117a, that is, a 1-1-th optical layer 117a1 may be formed first. The 1-1-th optical layer 117a1 may form the first optical layer 117a together with a 1-2-th optical layer 117a2 and a 1-3-th optical layer 117a3. The 1-1-th optical layer 117a1 may be disposed so as to cover the bank BNK, the passivation layer 116, and the first electrode CE1. At this time, the solder pattern SDP may be exposed from the 1-1-th optical layer 117a1. The solder pattern SDP exposed from the 1-1-th optical layer 117a1 may be connected to the main micro LED (ED) and the redundancy micro LED (ED) in a subsequent process. Accordingly, in order to connect the solder pattern SDP and the micro LED (ED), the 1-1-th optical layer 117a1 may not cover the solder pattern SDP.

When the first optical layer 117a is formed, there may be a limitation in a thickness of the first optical layer 117a which may be formed by one process. Therefore, the thickness of the first optical layer 117a may be adjusted in various thicknesses by several processes. For example, the 1-1-th optical layer 117a1 is formed first, and then the 1-2-th optical layer 117a2 is formed to form a first optical layer 117a having a thickness enough to cover all the micro LED (ED) and the bank BNK, but the example embodiments of the present disclosure are not limited thereto.

Next, the 1-1-th micro LED 130a is transferred to the 1-1-th sub pixel SP1a. The 1-1-th micro LED 130a may be bonded to the solder pattern SDP exposed from the 1-1-th optical layer 117a1. Further, even though it is not illustrated in the drawing, the 2-1-th micro LED 140a and the 3-1-th micro LED 150a which are the main micro LEDs (ED) may also be transferred into the 2-1-th sub pixel SP2a and the 3-1-th sub pixel SP3a. The 1-1-th micro LED 130a, the 2-1-th micro LED 140a, and the 3-1-th micro LED 150a may be sequentially transferred or may also be simultaneously transferred, and are not limited thereto.

Referring to FIG. 11B, the 1-2-th optical layer 117a2 is formed in the 1-1-th sub pixel SP1a. The 1-2-th optical layer 117a2 may be formed so as to enclose the 1-1-th micro LED 130a of the 1-1-th sub pixel SP1a on the 1-1-th optical layer 117a1. For example, the 1-2-th optical layer 117a2 is formed so as to cover the 1-1-th micro LED 130a to suppress the disconnection of the test electrode TE or the second electrode CE2 formed on the 1-1-th micro LED 130a and fix and protect the 1-1-th micro LED 130a. For example, the 1-2-th optical layer 117a2 may be partially formed only in the 1-1-th sub pixel SP1a. Further, even though it is not illustrated in the drawing, the 1-2-th optical layer 117a2 may be formed on the 1-1-th optical layer 117a1 also in the 2-1-th sub pixel SP2a and the 3-1-th sub pixel SP3a. That is, in the 1-1-th sub pixel SP1a, the 2-1-th sub pixel SP2a, and the 3-1-th sub pixel SP3a to which the main micro LED (ED) is transferred, the 1-2-th optical layer 117a2 may be formed.

Next, the test electrode TE is formed on the 1-2-th optical layer 117a2 and the 1-1-th micro LED 130a. The test electrode TE may temporarily transmit a cathode voltage to a cathode electrode 135a of the 1-1-th micro LED 130a. During the lighting test, the test electrode TE is applied with the cathode voltage from any one of an external power or a pixel driving circuit PD to transmit the cathode voltage to the main micro LED (ED). The test electrode TE may be removed after testing whether the main micro LED (ED) is lit.

Next, a voltage is applied to the first electrode CE1 and the test electrode TE to drive the 1-1-th micro LED 130a. The defect of the 1-1-th sub pixel SP1a may be detected by testing whether the 1-1-th micro LED 130a emits light. For example, the lighting failure of the 1-1-th sub pixel SP1a may be caused due to a connection error of the first electrode CE1 and the test electrode TE and the 1-1-th micro LED 130a due to misalignment of the 1-1-th micro LED 130a, a defect of the 1-1-th micro LED 130a, or a non-transferring defect of the 1-1-th micro LED 130a. Therefore, before transferring the redundancy micro LED (ED), the main micro LED (ED) is tested in advance to determine whether to additionally transfer the redundancy micro LED (ED).

Referring to FIG. 11C, when the 1-1-th sub pixel SP1a is defective, the 1-2-th micro LED 130b is transferred to the 1-2-th sub pixel SP1b. For example, the test electrode TE may be removed after the lighting test. Next, the 1-2-th micro LED 130b may be transferred to the solder pattern SDP of the 1-2-th sub pixel SP1b.

Referring to FIG. 11D, the 1-3-th optical layer 117a3 is formed in the 1-2-th sub pixel SP1b. The 1-3-th optical layer 117a3 may be formed so as to enclose the 1-2-th micro LED 130b of the 1-2-th sub pixel SP2b on the 1-1-th optical layer 117a1. The 1-3-th optical layer 117a3 may form the first optical layer 117a together with a 1-1-th optical layer 117a1 and a 1-2-th optical layer 117a2. The 1-3-th optical layer 117a3 may be partially formed only in the 1-2-th sub pixel SP1b. The 1-3-th optical layer 117a3 may form the first optical layer 117a together with a 1-1-th optical layer 117a1 and a 1-2-th optical layer 117a2. Further, even though it is not illustrated in the drawing, the 1-3-th optical layer 117a3 may be formed on the 1-1-th optical layer 117a1 also in the 2-2-th sub pixel SP2b and the 3-2-th sub pixel SP3b. That is, in the 1-2-th sub pixel SP1b, the 2-2-th sub pixel SP2b, and the 3-2-th sub pixel SP3b to which the main micro LED (ED) is transferred, the 1-3-th optical layer 117a3 may be formed. Finally, the first optical layer 117a may be formed by the 1-1-th optical layer 117a1 formed before transferring the main micro LED (ED), the 1-2-th optical layer 117a2 formed after transferring the main micro LED (ED), and the 1-3-th optical layer 117a3 formed after transferring the redundancy micro LED (ED).

Next, the second electrode CE2 is formed on the first optical layer 117a. The second electrode CE2 is formed on the plurality of micro LEDs (ED) and the first optical layer 117a to be electrically connected to the plurality of micro LEDs (ED).

Next, the third optical layer 117c is formed on the second electrode CE2. The third optical layer 117c may be formed so as to correspond to an area of the plurality of sub pixels. The third optical layer 117c may be formed on the plurality of micro LEDs (ED).

Next, referring to FIGS. 10A, 10B, and 11D together, the black matrix BM is formed on the third optical layer 117c. At this time, a transmission holes of the black matrix BM may be formed so as to correspond to any one of one pair of first sub pixels SP1, any one of one pair of second sub pixels SP2, and any one of one pair of third sub pixels SP3. For example, when the 1-1-th sub pixel SP1a is defective and the 1-2-th sub pixel SP1b is normal, the transmission hole of the black matrix BM may be formed so as to correspond to the 1-2-th micro LED 130b of the 1-2-th sub pixel SP1b. For example, when the 2-1-th sub pixel SP2a is defective and the 2-2-th sub pixel SP2b is normal, the transmission hole of the black matrix BM may be formed so as to correspond to the 2-2-th micro LED 140b of the 2-2-th sub pixel SP2b. For example, when the 3-1-th sub pixel SP3a is normal and the 3-2-th micro LED 150b is not transferred to the 3-2-th sub pixel SP3b, the transmission hole of the black matrix BM may be formed so as to correspond to the 3-1-th micro LED 150a of the 3-1-th sub pixel SP3a. Accordingly, the black matrix BM may be disposed so as to cover at least a part of the plurality of micro LEDs (ED) and the plurality of transmission holes of the black matrix BM may be disposed so as to overlap only some sub pixel among the plurality of sub pixels.

Accordingly, in the display device 1000 according to the example embodiment of the present disclosure, after performing the lighting test by transferring the main micro LED (ED) first, the redundancy micro LED (ED) is additionally transferred depending on the result to save the manufacturing cost. For example, the main micro LED (ED) is transferred into the plurality of sub pixels and the test electrode TE is temporarily formed to perform the lighting test of the main micro LED (ED). When the main micro LED (ED) having a micro size is transferred from the wafer to the substrate 110, an electrode connection failure due to the alignment error or the defect that the main micro LED (ED) is not transferred may occur. Accordingly, the lighting test is performed to detect a defective sub pixel which does not emit light. Next, the redundancy micro LED (ED) may be additionally transferred only to a redundancy sub pixel which is adjacent to the defective sub pixel. For example, when the 1-1-th sub pixel SP1a is defective, the 1-2-th micro LED 130b is additionally transferred to the 1-2-th sub pixel SP1b to use the 1-2-th sub pixel SP1b instead of the 1-1-th sub pixel SP1a. Accordingly, the redundancy micro LED (ED) is additionally transferred to only some sub pixel based on the detection result of a defective sub pixel so that a minimum number of redundancy micro LEDs (ED) may be used. The number of redundancy micro LEDs (ED) may be smaller than the number of main micro LEDs (ED). Therefore, a total number of micro LEDs (ED) is reduced so that the manufacturing cost may be saved.

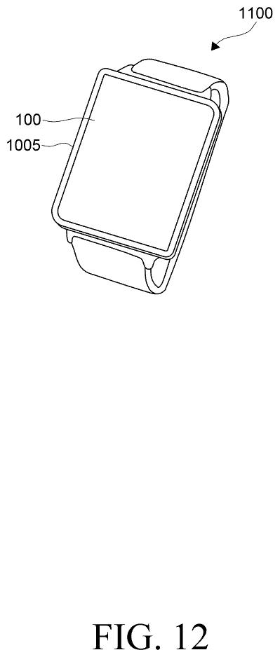

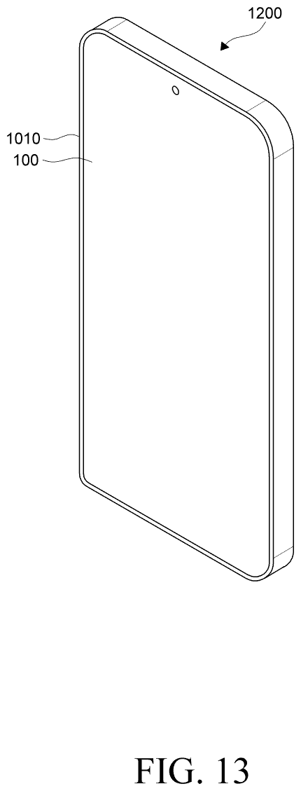

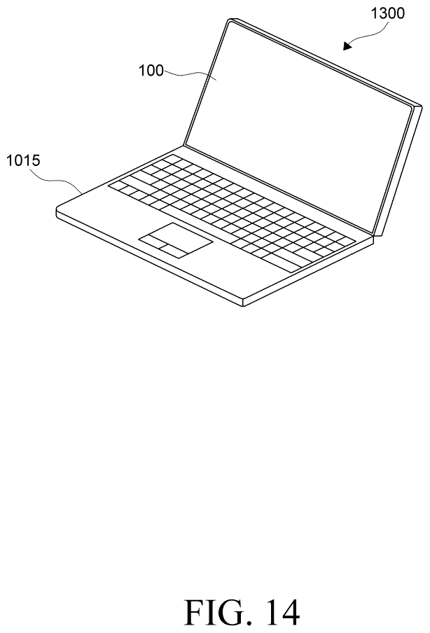

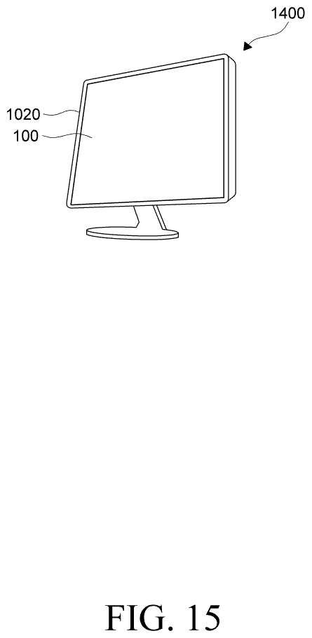

FIGS. 12 to 15 are views illustrating devices to which a display device according to example embodiments of the present disclosure is applied.

Referring to FIGS. 12 to 15, the display device 1000 according to the example embodiments of the present disclosure may be included in various devices or electronic devices. For example, referring to FIGS. 12 to 15, various electronic device may include a wearable device 1100, a mobile device 1200, a notebook 1300, and a monitor or TV 1400, but the example embodiments of the present disclosure are not limited thereto.

The wearable device 1100, the mobile device 1200, the notebook 1300, and a monitor or TV 1400 may include case units 1005, 1010, 1015, and 1020 and display panel 100 and the display device 1000 according to the example embodiments of the present disclosure which have been described in FIGS. 1 to 11D, respectively.

For example, the display device 1000 according to the example embodiment of the present disclosure may be applicable to a mobile device, a video phone, a smart watch, a watch phone, a wearable device, a foldable device, a rollable device, a bendable device, a flexible device, a curved device, a sliding device, a variable device, an electronic note, an electronic book, a portable multimedia player (PMP), a personal digital assistant (PDA), an MP3 player, a mobile medical device, a desktop PC, a laptop PC, a netbook computer, a workstation, a navigation, a display device for a vehicle, a theatrical display device, a television, a wallpaper device, a signage device, a game device, a notebook, a monitor, a camera, a camcorder, and a consumer electronics device.

The example embodiments of the present disclosure can also be described as follows:

According to an aspect of the present disclosure, a display device may include a substrate; a pixel configured by a plurality of main sub pixels and a plurality of redundancy sub pixels; at least one pixel driving circuit disposed on the substrate; a plurality of main micro light emitting diodes (LEDs) which is disposed on the pixel driving circuit and is electrically connected to the pixel driving circuit; and a plurality of redundancy micro LEDs which is disposed on the pixel driving circuit and is electrically connected to the pixel driving circuit and the plurality of main micro LEDs is disposed in the plurality of main sub pixels and the plurality of redundancy micro LEDs is disposed in at least some of the plurality of redundancy sub pixels.

The display device may further include a plurality of first electrodes which is electrically connected to the plurality of main micro LEDs and the plurality of redundancy micro LEDs, respectively, and a plurality of signal lines which electrically connects the plurality of first electrodes and the pixel driving circuit. The plurality of first electrodes and the plurality of signal lines may be configured to transmit an anode voltage output from the pixel driving circuit to the plurality of main micro LEDs and the plurality of redundancy micro LEDs.

The display device may further include a plurality of contact electrodes which is electrically connected to the pixel driving circuit, and one or more second electrodes which are electrically connected to the plurality of contact electrodes. The second electrodes and the plurality of contact electrodes may be configured to transmit a cathode voltage output from the pixel driving circuit to the plurality of main micro LEDs and the plurality of redundancy micro LEDs.

The display device may further include a plurality of banks which supports the plurality of main micro LEDs and the plurality of redundancy micro LEDs. The plurality of first electrodes may be disposed between the plurality of main micro LEDs and between the plurality of banks and the plurality of redundancy micro LEDs and the plurality of banks.

The plurality of main sub pixels may include at least one defective main sub pixel and the plurality of redundancy micro LEDs may be disposed in at least one redundancy sub pixel adjacent to the at least one defective main sub pixels, among the plurality of redundancy sub pixels.

The plurality of redundancy micro LEDs may be disposed in only some of the plurality of redundancy sub pixels.

The number of the plurality of main micro LEDs may be larger than the number of the plurality of redundancy micro LEDs.

The display device may further include a black matrix disposed on the plurality of main micro LEDs and the plurality of redundancy micro LEDs. The black matrix may include a plurality of transmission holes which overlaps at least some of the plurality of main micro LEDs and all of the plurality of redundancy micro LEDs.

Each of the plurality of main micro LEDs and the plurality of redundancy micro LEDs may include an anode electrode, a first semiconductor layer disposed on the anode electrode, an active layer on the first semiconductor layer, a second semiconductor layer on the active layer, and a cathode electrode on the second semiconductor layer.

The display device may further include a solder pattern which is disposed between each of the plurality of first electrodes and the anode electrode. The plurality of first electrodes and the anode electrodes may be electrically connected by eutectic bonding using the solder pattern.

According to another aspect of the present disclosure, a display device may include a substrate, a plurality of pixels each including one pair of first sub pixels, wherein the one pair of first sub pixels includes a 1-1-th sub pixel and a 1-2-th sub pixel, a first micro light emitting diode (LED) which is disposed in at least one sub pixel of the one pair of first sub pixels, and a black matrix which includes a transmission hole overlapping one sub pixel of the one pair of first sub pixels. The plurality of pixels includes a first pixel in which the first micro LED is disposed in the 1-1-th sub pixel in the one pair of first sub pixels, a second pixel in which the first micro LED is disposed in the 1-2-th sub pixel in the one pair of first sub pixels, and a third pixel in which the first micro LED is disposed in each sub pixel of the one pair of first sub pixels.

In the first pixel in which the first micro LED is disposed in the 1-1-th sub pixel, the 1-1-th sub pixel may be a main sub pixel and the 1-2-th sub pixel may be a redundancy sub pixel.

The transmission hole of the black matrix may overlap the 1-1-th sub pixel in the 1-1-th sub pixel and the 1-2-th sub pixel.

In the second pixel in which the first micro LED is disposed in the 1-2-th sub pixel, the

1-1-th sub pixel may be a defective sub pixel.

The transmission hole of the black matrix may overlap the 1-2-th sub pixel in the 1-1-th sub pixel and the 1-2-th sub pixel.

In the third pixel in which the first micro LED is disposed in each sub pixel of the one pair of first sub pixels, the first micro LED of the 1-1-th sub pixel may be configured so as not to emit light and the first micro LED of the 1-2-th sub pixel may be configured so as to emit light.

In the third pixel in which the first micro LED is disposed in each sub pixel of the one pair of first sub pixels, the 1-1-th sub pixel may be a defective sub pixel.

The transmission hole of the black matrix may overlap the 1-2-th sub pixel in the 1-1-th sub pixel and the 1-2-th sub pixel.

The first micro LED disposed in the 1-1-th sub pixel may overlap the black matrix.

The black matrix may be disposed so as to cover at least a part of the first micro LED.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a pixel configured by a plurality of main sub pixels and a plurality of redundancy sub pixels;
at least one pixel driving circuit disposed on the substrate;
a plurality of main micro light emitting diodes (LEDs) which is disposed on the pixel driving circuit and is electrically connected to the pixel driving circuit; and
a plurality of redundancy micro LEDs which is disposed on the pixel driving circuit and is electrically connected to the pixel driving circuit,
wherein the plurality of main micro LEDs is disposed in the plurality of main sub pixels and the plurality of redundancy micro LEDs is disposed in at least some of the plurality of redundancy sub pixels.

2. The display device according to claim 1, further comprising:
a plurality of first electrodes which is electrically connected to the plurality of main micro LEDs and the plurality of redundancy micro LEDs, respectively; and
a plurality of signal lines which electrically connects the plurality of first electrodes and the pixel driving circuit,
wherein the plurality of first electrodes and the plurality of signal lines are configured to transmit an anode voltage output from the pixel driving circuit to the plurality of main micro LEDs and the plurality of redundancy micro LEDs.

3. The display device according to claim 2, further comprising:
a plurality of contact electrodes which is electrically connected to the pixel driving circuit; and
one or more second electrodes which are electrically connected to the plurality of contact electrodes,
wherein the second electrodes and the plurality of contact electrodes are configured to transmit a cathode voltage output from the pixel driving circuit to the plurality of main micro LEDs and the plurality of redundancy micro LEDs.

4. The display device according to claim 2, further comprising:
a plurality of banks which supports the plurality of main micro LEDs and the plurality of redundancy micro LEDs,
wherein the plurality of first electrodes is disposed between the plurality of main micro LEDs and the plurality of banks and between the plurality of redundancy micro LEDs and the plurality of banks.

5. The display device according to claim 1, wherein the plurality of main sub pixels includes at least one defective main sub pixel, and the plurality of redundancy micro LEDs is disposed in at least one redundancy sub pixel adjacent to the at least one defective main sub pixels, among the plurality of redundancy sub pixels.

6. The display device according to claim 1, wherein the plurality of redundancy micro LEDs is disposed in only some of the plurality of redundancy sub pixels.

7. The display device according to claim 1, wherein a number of the plurality of main micro LEDs is larger than a number of the plurality of redundancy micro LEDs.

8. The display device according to claim 1, further comprising:
a black matrix disposed on the plurality of main micro LEDs and the plurality of redundancy micro LEDs,
wherein the black matrix includes a plurality of transmission holes which overlaps at least some of the plurality of main micro LEDs and all of the plurality of redundancy micro LEDs.

9. The display device according to claim 2, wherein each of the plurality of main micro LEDs and the plurality of redundancy micro LEDs includes:
an anode electrode;
a first semiconductor layer disposed on the anode electrode;
an active layer on the first semiconductor layer;
a second semiconductor layer on the active layer; and
a cathode electrode on the second semiconductor layer.

10. The display device according to claim 9, further comprising:
a solder pattern which is disposed between each of the plurality of first electrodes and the anode electrode,
wherein the plurality of first electrodes and the anode electrodes are electrically connected by eutectic bonding using the solder pattern.

11. A display device, comprising:
a substrate;
a plurality of pixels each including one pair of first sub pixels, wherein the one pair of first sub pixels includes a 1-1-th sub pixel and a 1-2-th sub pixel;
a first micro light emitting diode (LED) which is disposed in at least one sub pixel of the one pair of first sub pixels; and
a black matrix which includes a transmission hole overlapping one sub pixel of the one pair of first sub pixels,
wherein the plurality of pixels includes a first pixel in which the first micro LED is disposed in the 1-1-th sub pixel in the one pair of first sub pixels, a second pixel in which the first micro LED is disposed in the 1-2-th sub pixel in the one pair of first sub pixels, and a third pixel in which the first micro LED is disposed in each sub pixel of the one pair of first sub pixels.

12. The display device according to claim 11, wherein in the first pixel in which the first micro LED is disposed in the 1-1-th sub pixel, the 1-1-th sub pixel is a main sub pixel and the 1-2-th sub pixel is a redundancy sub pixel.

13. The display device according to claim 12, wherein the transmission hole of the black matrix overlaps the 1-1-th sub pixel in the 1-1-th sub pixel and the 1-2-th sub pixel.

14. The display device according to claim 11, wherein in the second pixel in which the first micro LED is disposed in the 1-2-th sub pixel, the 1-1-th sub pixel is a defective sub pixel.

15. The display device according to claim 14, wherein the transmission hole of the black matrix overlaps the 1-2-th sub pixel in the 1-1-th sub pixel and the 1-2-th sub pixel.

16. The display device according to claim 11, wherein in the third pixel in which the first micro LED is disposed in each sub pixel of the one pair of first sub pixels, the first micro LED of the 1-1-th sub pixel is configured so as not to emit light and the first micro LED of the 1-2-th sub pixel is configured so as to emit light.

17. The display device according to claim 16, wherein in the third pixel in which the first micro LED is disposed in each sub pixel of the one pair of first sub pixels, the 1-1-th sub pixel is a defective sub pixel.

18. The display device according to claim 16, wherein the transmission hole of the black matrix overlaps the 1-2-th sub pixel in the 1-1-th sub pixel and the 1-2-th sub pixel.

19. The display device according to claim 18, wherein the first micro LED disposed in the 1-1-th sub pixel overlaps the black matrix.

20. The display device according to claim 11, wherein the black matrix is disposed so as to cover at least a part of the first micro LED.
